(19) United States
(12) Patent Application Publication
(10) Pub. No.: US 2020/0270517 A1
(43) Pub. Date: Aug. 27, 2020

(54) NANOCRYSTAL ASSEMBLIES AND USES THEREOF

(71) Applicants: Satria Zulkarnaen Bisri, Saitama (JP); Thomas Kugler, Cambridge (GB); Ian Johnson, Godmanchester (GB); Jeremy Burroughes, Cambridge (GB); Yoshihiro Iwasa, Saitama (JP); Yasuhiro Ishida, Saitama (JP); Liming Liu, Saitama (JP)

(72) Inventors: Satria Zulkarnaen Bisri, Saitama (JP); Thomas Kugler, Cambridge (GB); Ian Johnson, Godmanchester (GB); Jeremy Burroughes, Cambridge (GB); Yoshihiro Iwasa, Saitama (JP); Yasuhiro Ishida, Saitama (JP); Liming Liu, Saitama (JP)

(73) Assignees: Sumitomo Chemical Company Limited, Tokyo (JP); RIKEN, Wako-Shi (JP)

(21) Appl. No.: 16/796,847

(22) Filed: Feb. 20, 2020

Related U.S. Application Data
(60) Provisional application No. 62/809,519, filed on Feb. 22, 2019.

(51) Int. Cl. C09K 11/06; C09K 11/66; H01L 35/26; H01L 29/12

(52) U.S. Cl. CPC C09K 11/06; H01L 29/127; H01L 35/26; C09K 11/661

(57) ABSTRACT

Provided herein are nanocrystal assemblies comprising quantum dots, a dopant (e.g., an organic compound dopant), and a ligand bridging the quantum dots. Also provided are methods of preparing the assemblies and devices comprising the assemblies (e.g., field effect transistors, thermoelectric generators).

### RELATED APPLICATIONS

This application claims priority under 35 U.S.C. § 119(e) to U.S. Provisional Patent Application Ser. No. 62/809,519, filed Feb. 22, 2019, the entirety of which is incorporated herein by reference.

### BACKGROUND

Colloidal quantum dots (CQDs) are solution-processable semiconductor nanocrystals that are useful in fabricating a variety of optoelectronic devices, such as solar cells, photodetectors, and field-effect transistors. The small size of the nanocrystals leads them to exhibit the quantum confinement effect which generates energy bandgap value variations by size and forms discrete energy levels. To stabilize the nanocrystals and render them solution-processable, insulating long-chain organic molecular ligands (e.g., oleic acid) are used to passivate the nanocrystal surface. However, these long ligands inhibit charge carrier transport in the fabricated electronic devices. In order to couple the nanocrystals to a transport charge carrier, the long ligands are typically replaced by shorter ligands (e.g., 1,2-ethanedithiol, 3-mercaptopropionic acid, oxalic acid, iodide). While this ligand exchange may enhance the charge carrier transport, the morphology of the formed films is typically disrupted due to the volume shrinkage of the nanocrystal assemblies, leaving cracks and disorders.

### SUMMARY

In order to prepare assemblies of semiconductor nanocrystals (e.g., quantum dots) that are advantageous in a variety of applications and devices, the present disclosure contemplates novel doping and/or novel ligand design of the assemblies.

In one aspect, provided is a nanocrystal assembly comprising: quantum dots; a dopant comprising an organic compound; and a ligand bridging the quantum dots.

In certain embodiments, the quantum dots are colloidal quantum dots.

In certain embodiments, the quantum dots comprise InSb, InGaP, PbS, PbSe, PbTe, PbI₂, HgS, HgTe, LaF₃, CdS, CulnS₂, CdTe, CuZnInS₂, CdSe, HfO₂, CIS, CZTS, YV(B)O₄, ZnS, ZrO₂, PbSₓSe₍₁₋ₓ₎, HgₓCd₍₁₋ₓ₎Te, InAs₍₁₋ₓ₎Sbₓ, or AlₓGa₍₁₋ₓ₎As, or combinations thereof.

In certain embodiments, the quantum dots comprise PbS.

In certain embodiments, the dopant is an n-type dopant.

In certain embodiments, the dopant is of the formula:

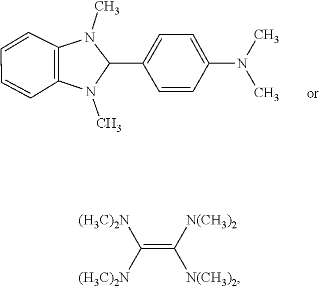

or salts thereof.

In certain embodiments, the dopant further comprises an inorganic salt.

In certain embodiments, the dopant further comprises LiClO₄.

In certain embodiments, the ligand is of the formula:

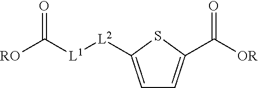

or a salt thereof, wherein:

each R is independently hydrogen, substituted or unsubstituted alkyl, substituted or unsubstituted aryl, substituted or unsubstituted heteroaryl, or substituted or unsubstituted heterocyclyl;

L¹ is a bond, substituted or unsubstituted heteroarylene, substituted or unsubstituted arylene, substituted or unsubstituted alkenylene, or substituted or unsubstituted alkynylene; and

L² is a bond, substituted or unsubstituted heteroarylene, substituted or unsubstituted arylene, substituted or unsubstituted alkenylene, or substituted or unsubstituted alkynylene; provided that L¹ and L² are not both a bond at the same time.

In certain embodiments, each R is independently R is hydrogen or substituted or unsubstituted alkyl; L¹ is a bond, substituted or unsubstituted heteroarylene, or substituted or unsubstituted alkenylene; and L² is a bond, substituted or unsubstituted heteroarylene, or substituted or unsubstituted alkenylene.

In certain embodiments, the ligand is of the formula:

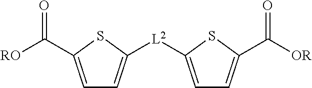

or a salt thereof.

In certain embodiments, the ligand is of the formula:

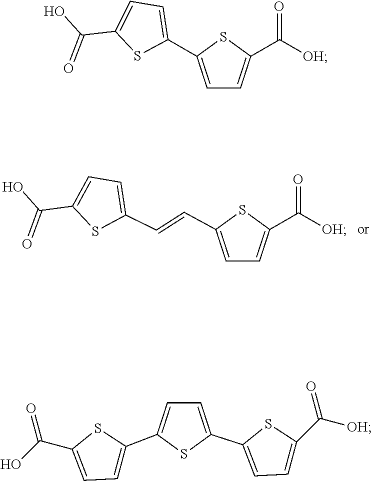 [SMILES: O=C(O)c1ccc(-c2ccc(C(=O)O)s2)s1 ; O=C(O)c1ccc(/C=C/c2ccc(C(=O)O)s2)s1 ; O=C(O)c1ccc(-c2ccc(-c3ccc(C(=O)O)s3)s2)s1]

or a salt thereof

In certain embodiments, the quantum dots are cross-linked. In certain embodiments, substantially all of the quantum dots are cross-linked.

In certain embodiments, the assembly comprises a thin film lattice.

In another aspect, provided is a nanocrystal assembly comprising: quantum dots; a dopant; and a ligand bridging the quantum dots, wherein the bridging ligand is of the formula:

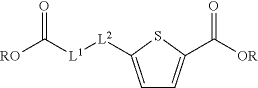

or a salt thereof, wherein:

each R is independently R is hydrogen, substituted or unsubstituted alkyl, substituted or unsubstituted aryl, substituted or unsubstituted heteroaryl, or substituted or unsubstituted heterocyclyl;

L¹ is a bond, substituted or unsubstituted heteroarylene, substituted or unsubstituted arylene, substituted or unsubstituted alkenylene, or substituted or unsubstituted alkynylene; and

L² is a bond, substituted or unsubstituted heteroarylene, substituted or unsubstituted arylene, substituted or unsubstituted alkenylene, or substituted or unsubstituted alkynylene; provided that L¹ and L² are not both a bond at the same time.

In certain embodiments, each R is independently R is hydrogen or substituted or unsubstituted alkyl; L¹ is a bond, substituted or unsubstituted heteroarylene, or substituted or unsubstituted alkenylene; and L² is a bond, substituted or unsubstituted heteroarylene, or substituted or unsubstituted alkenylene.

In certain embodiments, the ligand is of the formula:

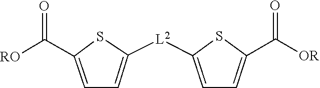

or a salt thereof

In certain embodiments, the ligand is of the formula:

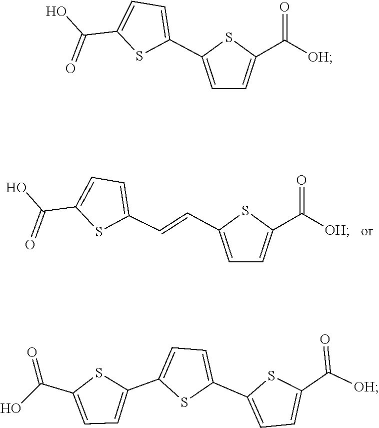 [SMILES: O=C(O)c1ccc(-c2ccc(C(=O)O)s2)s1 ; O=C(O)c1ccc(/C=C/c2ccc(C(=O)O)s2)s1 ; O=C(O)c1ccc(-c2ccc(-c3ccc(C(=O)O)s3)s2)s1]

or a salt thereof.

In certain embodiments, the quantum dots are colloidal quantum dots.

In certain embodiments, the quantum dots comprise InSb, InGaP, PbS, PbSe, PbTe, PbI₂, HgS, HgTe, LaF₃, CdS, CulnS₂, CdTe, CuZnInS₂, CdSe, HfO₂, CIS, CZTS, YV(B)O₄, ZnS, ZrO₂, PbSₓSe₍₁₋ₓ₎, HgₓCd₍₁₋ₓ₎Te, InAs₍₁₋ₓ₎Sbₓ, or AlₓGa₍₁₋ₓ₎As, or combinations thereof.

In certain embodiments, the quantum dots comprise PbS.

In certain embodiments, the dopant is an n-type dopant.

In certain embodiments, the dopant is of the formula:

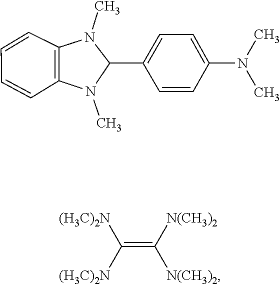

or salts thereof.

In certain embodiments, the dopant further comprises an inorganic salt.

In certain embodiments, the dopant further comprises LiClO₄.

In certain embodiments, the quantum dots are cross-linked. In certain embodiments, substantially all of the quantum dots are cross-linked.

In certain embodiments, the assembly comprises a thin film lattice.

In certain embodiments, the device is a field effect transistor. In certain embodiments, the device is a thermoelectric generator. In certain embodiments, the device is fabricated by solution processing the assembly.

In another aspect, provided are methods of preparing the device, the method comprising solution processing the assembly.

In another aspect, provided are methods of preparing the assembly of any of claims 1-30, the method comprising: (a) depositing the quantum dots on a substrate; (b) combining the bridging ligand with the quantum dots such that any native ligand on the quantum dots is exchanged with the bridging ligand; (c) spin casting to form a film; (d) heating the film; and (e) adding the dopant to the film in solvent via spin casting to form the assembly.

In certain embodiments, steps (a)-(c) are sequentially repeated at least four times before heating.

The details of one or more embodiments of the invention are set forth in the accompanying Figures and the Detailed Description below. Other features, objects, and advantages of the invention will be apparent from the Examples and the Claims.

### BRIEF DESCRIPTION OF THE DRAWINGS

FIG. 1 is a graph showing absorbance vs. wavelength (raw data) for a thin film doped with DMBI.

FIG. 2 is a graph showing absorbance vs. wavelength (normalized data) for a thin film doped with DMBI.

FIG. 3 is a graph showing absorbance vs. wavelength (raw data) for a thin film doped with LiClO₄.

FIG. 4 is a graph showing absorbance vs. wavelength (normalized data) for a thin film doped with LiClO₄.

FIG. 5 is a graph showing absorbance vs. wavelength (raw data) for a thin film doped with DMBI:LiClO₄.

FIG. 6 is a graph showing absorbance vs. wavelength (normalized data) for a thin film doped with DMBI:LiClO₄.

FIG. 7 is a graph showing absorbance vs. wavelength (raw data) for a thin film doped with TDAE.

FIG. 8 is a graph showing absorbance vs. wavelength (normalized data) for a thin film doped with TDAE.

FIG. 9 is a graph showing absorbance vs. wavelength (raw data) for a thin film doped with TDAE:LiClO₄.

FIG. 10 is a graph showing absorbance vs. wavelength (normalized data) for a thin film doped with TDAE:LiClO₄.

FIG. 11 is a graph showing drain current vs. drain voltage for a pristine FET (no doping) demonstrating p-type behavior.

FIG. 12 is a graph showing drain current vs. drain voltage for an FET with DMBI:LiClO₄ doping, demonstrating n-type behavior.

FIG. 13 is a graph showing drain current vs. drain voltage for an FET with DMBI doping, demonstrating p-type behavior.

FIG. 14 is a graph showing FET transfer curve results. The solid line represents an FET with 1,2-ethanedithiol as ligand; the dotted line represents an FET with Ligand 1; the dashed/dotted dot line represents an FET with Ligand 2; and the dashed line represents an FET with Ligand 3. The transfer curve was measured with a drain voltage of −6 volts. The reverse sweep is shown in the graph.

### DETAILED DESCRIPTION

The inventors herein have recognized and discovered that chemical doping of nanocrystal assemblies (e.g., with an organic compound) and/or incorporating novel ligands on the surface of quantum dots of the assemblies provides semiconductor materials having beneficial properties useful for constructing devices with advantageous performance properties.

Nanocrystal assemblies comprising quantum dots are useful active materials for devices such as thermoelectric generators (TEGs). In order to be useful as TEGs, however, the materials should have a suitable figure of merit (ZT), which may be realized when the materials have low thermal conductivity (K), high electrical conductivity (a), and a large Seebeck coefficient (S). The ZT may change with temperature. Merely by way of example, figures of merit in a range of 0.75 or greater may provide for a suitable material for a TEG.

The present disclosure contemplates that increasing both the electrical conductivity and Seebeck coefficient may be achieved by chemical doping of the QDs (e.g., with an organic compound). In certain embodiments, the organic compound (e.g., n-DMBI) dopant's doping ability may be improved upon combination with an inorganic salt (e.g., LiClO4).

Minimizing volume shrinkage and increasing conductivity by designing and incorporating improved ligands that interconnect QDs in ordered assemblies is useful for many applications. QDs are often formed and stabilized by surrounding the core with a surfactant shell that keeps the QDs isolated and prevents charge transport though the arrays. Replacing this shell with shorter molecules (e.g., ligands) decreases the interparticle distance and increases the electronic coupling of the QDs, resulting in the formation of conductive assemblies. Controlling the structure and length of the ligands allows the assemblies to be tuned according to desired properties (e.g, conductivity). The structure and length of the ligands also impacts the ability of the chemical dopant to dope QDs within a lattice by controlling the free space around the QDs. Such ligand design, as disclosed herein, is useful to achieve an increase in electrical conductivity of QD assemblies. Thus, QD performance in devices such as TEGs and field effect transistors (FETs) may be improved upon incorporating dopants and/or novel ligand design.

### Nanocrystal Assembly

Provided are nanocrystal assemblies comprising: quantum dots; a dopant comprising an organic compound; and a ligand bridging the quantum dots.

Also provided are nanocrystal assemblies comprising: quantum dots; a dopant; and a ligand bridging the quantum dots, wherein the bridging ligand is of the formula:

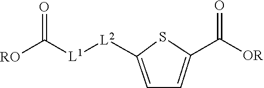

or a salt thereof, wherein:

each R is independently R is hydrogen, substituted or unsubstituted alkyl, substituted or unsubstituted aryl, substituted or unsubstituted heteroaryl, or substituted or unsubstituted heterocyclyl;

L¹ is a bond, substituted or unsubstituted heteroarylene, substituted or unsubstituted arylene, substituted or unsubstituted alkenylene, or substituted or unsubstituted alkynylene; and

L² is a bond, substituted or unsubstituted heteroarylene, substituted or unsubstituted arylene, substituted or unsubstituted alkenylene, or substituted or unsubstituted alkynylene; provided that L¹ and L² are not both a bond at the same time.

### Quantum Dots

In certain embodiments, the quantum dots are colloidal quantum dots (CQDs). CQDs are semiconductor crystals that exhibit size-dependent optical and electronic properties through the quantum confinement effect. CQDs in proximity interact and experience electronic coupling that depends on their distance and on the properties of the surrounding medium. These features allow for control of electronic properties that may be exploited in energy harvesting and electronics applications. Alternatively, even without exploiting the size-dependent effects, the possibility of nanoscale engineering of the composition and crystallinity qualifies CQDs as useful building blocks for bottom-up fabrication of bulk materials.

CQD assemblies have a large specific surface area, resulting in lower coordination than in bulk. Changing the dielectric or chemical environment thus has a significant effect on the overall properties.

In certain embodiments, the quantum dots comprise InSb, InGaP, PbS, PbSe, PbTe, PbI₂, HgS, HgTe, LaF₃, CdS, CulnS₂, CdTe, CuZnInS₂, CdSe, HfO₂, CIS, CZTS, YV(B)O₄, ZnS, ZrO₂, PbSₓSe₍₁₋ₓ₎, HgₓCd₍₁₋ₓ₎Te, InAs₍₁₋ₓ₎Sbₓ, or AlₓGa₍₁₋ₓ₀As, or combinations thereof; wherein x is a positive integer. In certain embodiments, x is 1, 2, 3, 4, 5, 6, 7, 8, 9, or 10.

In certain embodiments, the quantum dots comprise InSb, InGaP, PbS, PbSe, PbTe, PbI₂, HgS, HgTe, LaF₃, CdS, CulnS₂, CdTe, CuZnInS₂, CdSe, HfO₂, CIS, CZTS, YV(B)O₄, ZnS, or ZrO₂, or combinations thereof. In certain embodiments, the quantum dots comprise InSb, InGaP, PbS, PbSe, PbTe, PbI₂, HgS, HgTe, LaF₃, CdS, CulnS₂, CdTe, CuZnInS₂, CdSe, HfO₂, CIS, CZTS, YV(B)O₄, ZnS, or ZrO₂.

In certain embodiments, the quantum dots comprise PbS. In certain embodiments, the quantum dots are PbS.

### Dopant

In certain embodiments, the dopant comprises an organic compound. In certain embodiments, the dopant is an organic compound. In certain embodiments, the dopant comprises a salt of an organic compound. In certain embodiments, the dopant comprises an organic compound and a salt. In certain embodiments, the dopant comprises a mixture of an organic compound and a salt. In certain embodiments, the dopant comprises a mixture of an organic compound and an inorganic salt. In certain embodiments, the dopant comprises an organic compound and an inorganic salt. Merely by way of example, in some embodiments, the dopant may comprise a mixture of an organic compound and LiClO₄ or derivatives thereof or the like. In certain embodiments, the dopant is an n-type dopant. In certain embodiments, the dopant is not a metal.

In certain embodiments, the dopant comprises a compound of the formula:

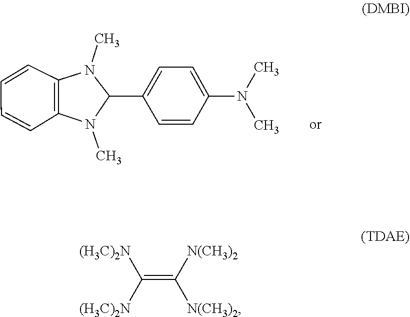

or a salt thereof.

In certain embodiments, the dopant is of the formula:

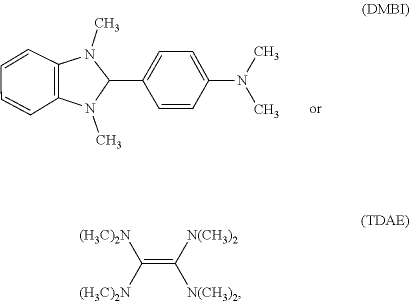

or a salt thereof.

In certain embodiments, the dopant comprises a compound of the formula:

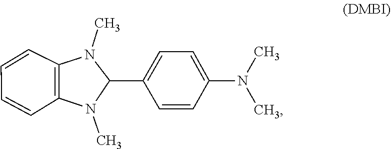

or a salt thereof.

In certain embodiments, the dopant is of the formula:

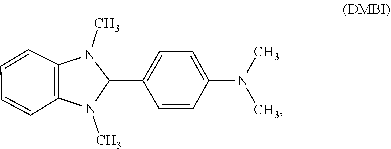

or a salt thereof.

In certain embodiments, the dopant comprises a compound of the formula:

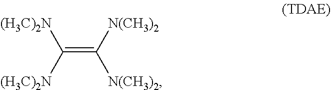

or a salt thereof.

In certain embodiments, the dopant is of the formula:

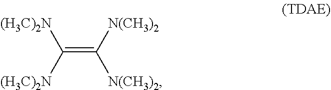

or a salt thereof.

In certain embodiments, the dopant comprises a compound of the formula:

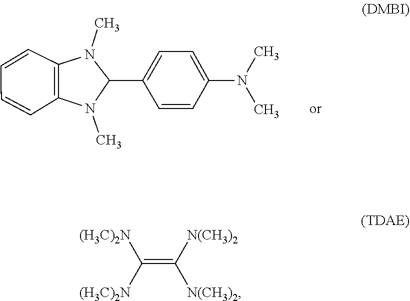

and a salt.

In certain embodiments, the dopant is a mixture of a compound of the formula:

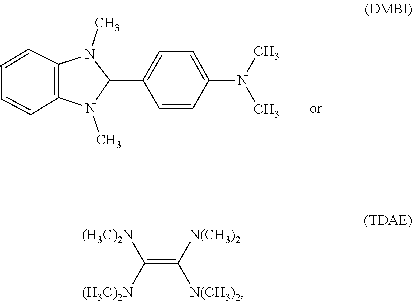

and a salt.

In certain embodiments, the dopant comprises a compound of the formula:

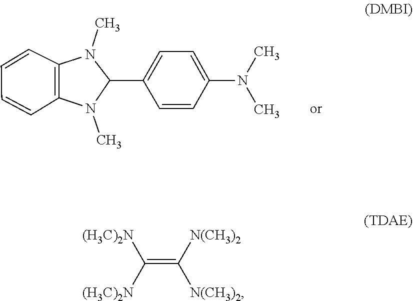

and an inorganic salt.

In certain embodiments, the dopant is a mixture of a compound of the formula:

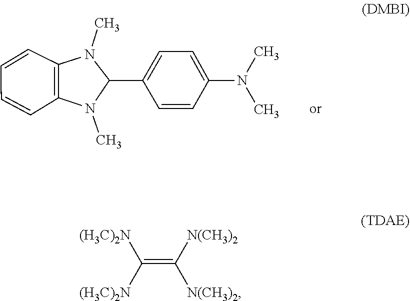

and an inorganic salt.

In certain embodiments, the dopant comprises a compound of the formula:

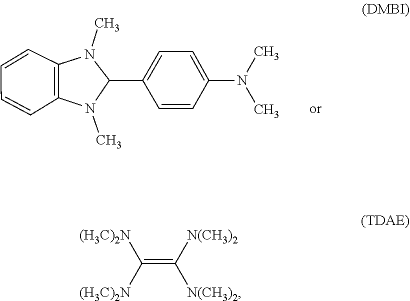

### and LiClO₄.

In certain embodiments, the dopant is a mixture of a compound of the formula:

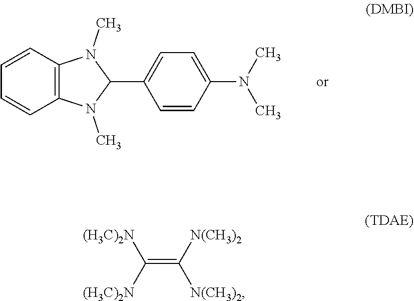

### and LiClO₄.

In certain embodiments, the dopant comprises a compound of the formula:

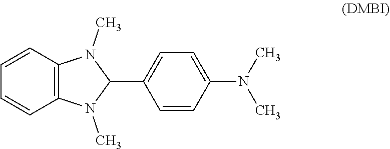 [SMILES: CN(C)c1ccc(C2N(C)c3ccccc3N2C)cc1]

### and LiClO₄.

In certain embodiments, the dopant is a mixture of a compound of the formula:

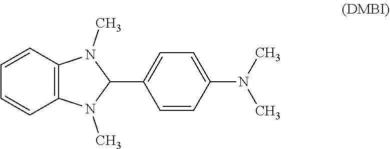 [SMILES: CN(C)c1ccc(C2N(C)c3ccccc3N2C)cc1]

### and LiClO₄.

In certain embodiments, the dopant comprises a compound of the formula:

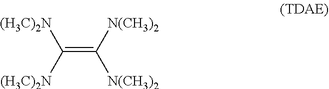

### and LiClO₄.

In certain embodiments, the dopant is a mixture of a compound of the formula:

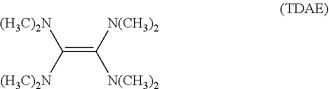

### and LiClO₄.

### Ligand

In certain embodiments, the ligands bridging the quantum dots are bidentate ligands. In certain embodiments, the ligands cross-link QDs (e.g., colloidal PbS QDs) to efficiently transport either holes or electrons. In certain embodiments, the end groups of the bidentate ligands influence the tendency of the transporting carrier in the assemblies. Even though some ligands of the present disclosure are significantly longer than known QD ligands, such as 1,2-ethanedithiol, employment of the presently described ligands in devices (e.g., FETs) demonstrate improved conductivity and on/off ratio characteristics over devices having known ligands. Thus, ligand structure may be selected based on the requirements of device applications such that the ligand enhances hole transport or electron transport.

In certain embodiments, the ligand is of the formula:

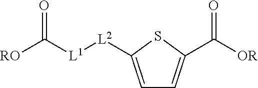

or a salt thereof, wherein:

each R is independently hydrogen, substituted or unsubstituted alkyl, substituted or unsubstituted aryl, substituted or unsubstituted heteroaryl, or substituted or unsubstituted heterocyclyl;

L¹ is a bond, substituted or unsubstituted heteroarylene, substituted or unsubstituted arylene, substituted or unsubstituted alkenylene, or substituted or unsubstituted alkynylene; and

L² is a bond, substituted or unsubstituted heteroarylene, substituted or unsubstituted arylene, substituted or unsubstituted alkenylene, or substituted or unsubstituted alkynylene; provided that L¹ and L² are not both a bond at the same time.

In certain embodiments, each R is independently hydrogen, substituted or unsubstituted alkyl, or substituted or unsubstituted heterocyclyl. In certain embodiments, each R is independently hydrogen or substituted or unsubstituted alkyl. In certain embodiments, each R is hydrogen.

In certain embodiments, L¹ is a bond, substituted or unsubstituted heteroarylene, or substituted or unsubstituted alkenylene. In certain embodiments, L¹ is a bond, substituted or unsubstituted thiophene, or substituted or unsubstituted alkenylene. In certain embodiments, L¹ is a bond, substituted or unsubstituted thiophene, or substituted or unsubstituted ethenylene. In certain embodiments, L¹ is a bond, unsubstituted thiophene, or unsubstituted ethenylene.

In certain embodiments, L¹ is substituted or unsubstituted heteroarylene. In certain embodiments, L¹ is unsubstituted heteroarylene. In certain embodiments, L¹ is substituted or unsubstituted thiophene. In certain embodiments, L¹ is unsubstituted thiophene. In certain embodiments, L¹ is a bond. In certain embodiments, L¹ is substituted or unsubstituted alkenylene. In certain embodiments, L¹ is substituted or unsubstituted ethenylene. In certain embodiments, L¹ is unsubstituted ethenylene.

In certain embodiments, L² is a bond, substituted or unsubstituted heteroarylene, or substituted or unsubstituted alkenylene. In certain embodiments, L² is a bond, substituted or unsubstituted thiophene, or substituted or unsubstituted alkenylene. In certain embodiments, L² is a bond, substituted or unsubstituted thiophene, or substituted or unsubstituted ethenylene. In certain embodiments, L² is a bond, unsubstituted thiophene, or unsubstituted ethenylene.

In certain embodiments, L² is substituted or unsubstituted heteroarylene. In certain embodiments, L² is unsubstituted heteroarylene. In certain embodiments, L² is substituted or unsubstituted thiophene. In certain embodiments, L² is unsubstituted thiophene. In certain embodiments, L² is a bond. In certain embodiments, L² is substituted or unsubstituted alkenylene. In certain embodiments, L² is substituted or unsubstituted ethenylene. In certain embodiments, L² is unsubstituted ethenylene.

In certain embodiments, L¹ is a bond, substituted or unsubstituted heteroarylene, or substituted or unsubstituted alkenylene; and L² is a bond, substituted or unsubstituted heteroarylene, or substituted or unsubstituted alkenylene. In certain embodiments, L¹ is a bond, substituted or unsubstituted thiophene, or substituted or unsubstituted alkenylene; and L² is a bond, substituted or unsubstituted thiophene, or substituted or unsubstituted alkenylene. In certain embodiments, L¹ is a bond, substituted or unsubstituted thiophene, or substituted or unsubstituted ethenylene; and L² is a bond, substituted or unsubstituted thiophene, or substituted or unsubstituted ethenylene. In certain embodiments, L¹ is a bond, unsubstituted thiophene, or unsubstituted ethenylene; and L² is a bond, unsubstituted thiophene, or unsubstituted ethenylene.

In certain embodiments, L¹ is substituted or unsubstituted heteroarylene; and L² is a bond, substituted or unsubstituted heteroarylene, or substituted or unsubstituted alkenylene. In certain embodiments, L¹ is substituted or unsubstituted thiophene; and L² is a bond, substituted or unsubstituted heteroarylene, or substituted or unsubstituted alkenylene. In certain embodiments, L¹ is substituted or unsubstituted thiophene; and L² is a bond, substituted or unsubstituted thiophene, or substituted or unsubstituted alkenylene. In certain embodiments, L¹ is substituted or unsubstituted thiophene; and L² is a bond, substituted or unsubstituted thiophene, or substituted or unsubstituted ethenylene. In certain embodiments, L¹ is unsubstituted thiophene; and L² is a bond, substituted or unsubstituted thiophene, or substituted or unsubstituted ethenylene. In certain embodiments, L¹ is unsubstituted thiophene; and L² is a bond, unsubstituted thiophene, or unsubstituted ethenylene.

In certain embodiments, each R is independently hydrogen, substituted or unsubstituted alkyl, or substituted or unsubstituted heterocyclyl; L¹ is a bond, substituted or unsubstituted heteroarylene, or substituted or unsubstituted alkenylene; and L² is a bond, substituted or unsubstituted heteroarylene, or substituted or unsubstituted alkenylene.

In certain embodiments, each R is independently hydrogen or substituted or unsubstituted alkyl; L¹ is a bond, substituted or unsubstituted heteroarylene, or substituted or unsubstituted alkenylene; and L² is a bond, substituted or unsubstituted heteroarylene, or substituted or unsubstituted alkenylene. In certain embodiments, each R is hydrogen; L¹ is a bond, substituted or unsubstituted heteroarylene, or substituted or unsubstituted alkenylene; and L² is a bond, substituted or unsubstituted heteroarylene, or substituted or unsubstituted alkenylene. In certain embodiments, each R is hydrogen; L¹ is substituted or unsubstituted heteroarylene; and L² is a bond, substituted or unsubstituted heteroarylene, or substituted or unsubstituted alkenylene. In certain embodiments, each R is hydrogen; L¹ is substituted or unsubstituted thiophene; and L² is a bond, substituted or unsubstituted heteroarylene, or substituted or unsubstituted alkenylene. In certain embodiments, each R is hydrogen; L¹ is substituted or unsubstituted thiophene; and L² is a bond, substituted or unsubstituted thiophene, or substituted or unsubstituted ethenylene. In certain embodiments, each R is hydrogen; L¹ is substituted or unsubstituted thiophene; and L² is a bond, unsubstituted thiophene, or unsubstituted ethenylene.

In certain embodiments, the ligand is of the formula:

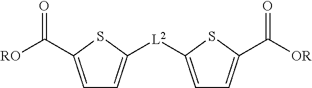

or a salt thereof, wherein R and L² are as defined herein.

In certain embodiments, the ligand is of the formula:

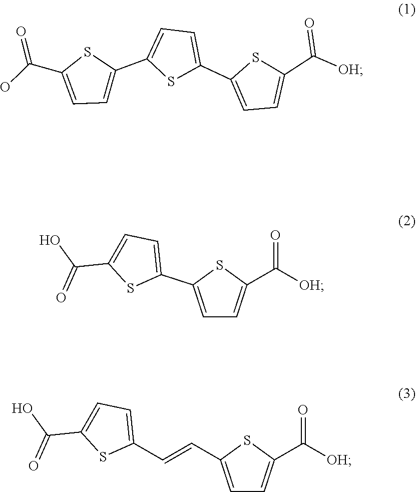 [SMILES: O=C(O)c1ccc(-c2ccc(-c3ccc(C(=O)O)s3)s2)s1 ; O=C(O)c1ccc(-c2ccc(C(=O)O)s2)s1 ; O=C(O)c1ccc(/C=C/c2ccc(C(=O)O)s2)s1]

or a salt thereof.

### Certain Embodiments

In certain embodiments of the assembly, the quantum dots are cross-linked. In certain embodiments of the assembly, at least 10% of the quantum dots are cross-linked. In certain embodiments of the assembly, at least 20% of the quantum dots are cross-linked. In certain embodiments of the assembly, at least 30% of the quantum dots are cross-linked. In certain embodiments of the assembly, at least 40% of the quantum dots are cross-linked. In certain embodiments of the assembly, at least 50% of the quantum dots are cross-linked. In certain embodiments of the assembly, at least 60% of the quantum dots are cross-linked. In certain embodiments of the assembly, at least 70% of the quantum dots are cross-linked. In certain embodiments of the assembly, at least 80% of the quantum dots are cross-linked. In certain embodiments of the assembly, at least 90% of the quantum dots are cross-linked. In certain embodiments of the assembly, at least 95% of the quantum dots are cross-linked. In certain embodiments of the assembly, at least 98% of the quantum dots are cross-linked. In certain embodiments of the assembly, at least 99% of the quantum dots are cross-linked. In certain embodiments of the assembly, substantially all of the quantum dots are cross-linked. In certain embodiments of the assembly, essentially all of the quantum dots are cross-linked.

In certain embodiments, the quantum dots are spaced by the ligands to form a lattice or similar arrangement. Merely by way of example, in certain embodiments, the assembly may comprise a thin film lattice or the like.

### Preparation of the Assemblies

The QDs may be formed by various synthetic techniques that include, but are not limited to, chemical synthesis (e.g, colloidal synthesis) and plasma synthesis, as distinguished from in-situ formation techniques such as vapor deposition and nanolithography. The size, size distribution, shape, surface chemistry or other attributes of the QDs may be engineered or tuned to have desired properties (e.g., photon absorption and/or emission) by any suitable technique.

Provided is a method of preparing the assembly, the method comprising:

(a) depositing the quantum dots on a substrate;

(b) combining the bridging ligand with the quantum dots such that any native ligand on the quantum dots is exchanged with the bridging ligand;

(c) spin casting to form a film;

(d) heating the film; and

(e) adding the dopant to the film in solvent via spin casting to form the assembly.

In certain embodiments, the QDs may be deposited on the substrate by any suitable method, particularly solution-based methods such as various known coating and printing methods, or doctor blading. In certain embodiments, after spin casting the film in step (c), the film is washed to remove unbound native ligand. In certain embodiments, steps (a)-(c) are repeated to form multiple layers of the film. In certain embodiments, steps (a)-(c) are repeated at least 1, 2, 3, 4, 5, 6, 7, 8, 9, or 10 times before heating in step (d).

### Devices

The present disclosure also provides devices comprising the assembly. In certain embodiments, the devices may comprise: photodetectors, solar cells, light-emitting devices (e.g., light-emitting field effect transistors), diode lasers, thermoelectric devices (e.g., TEGs) and/or the like.

In certain embodiments, the devices are field effect transistors (FETs). FETs are electronic devices which use an electric field to control the flow of current. FETs, besides being the fundamental building blocks of modern electronics, are often used to characterize the transport properties of semiconductors. For this purpose, simple device structures (bottom-gate, bottom-contact, and Si/SiO2 wafer as the gate stack) are typically employed. QD FETs, in particular CQD FETs, offer advantageous properties such as facile tuning of electronic properties, including fine-tuning of carrier concentration and mobility.

In certain embodiments, the devices are thermoelectric generators. A thermoelectric generator (TEG), also called a Seebeck generator, is a solid state device that converts heat flux (temperature differences) directly into electrical energy through a phenomenon called the Seebeck effect. CQDs are useful building blocks for nanostructured thermoelectric materials used to produce TEGs due to their ability to enhance the Seebeck coefficient.

### Chemical Definitions

Definitions of specific functional groups and chemical terms are described in more detail below. The chemical elements are identified in accordance with the Periodic Table of the Elements, CAS version, Handbook of Chemistry and Physics, 75th Ed., inside cover, and specific functional groups are generally defined as described therein. Additionally, general principles of organic chemistry, as well as specific functional moieties and reactivity, are described in Organic Chemistry, Thomas Sorrell, University Science Books, Sausalito, 1999; Smith and March, March's Advanced Organic Chemistry, 5th Edition, John Wiley & Sons, Inc., New York, 2001; Larock, Comprehensive Organic Transformations, VCH Publishers, Inc., New York, 1989; and Carruthers, Some Modern Methods of Organic Synthesis, 3rd Edition, Cambridge University Press, Cambridge, 1987.

Compounds described herein may comprise one or more stereogenic centers, and thus may exist as stereoisomers, e.g., enantiomers and/or diastereomers. For example, the compounds described herein can be in the form of an individual enantiomer, diastereomer or geometric isomer, or can be in the form of a mixture of stereoisomers, including racemic mixtures and mixtures enriched in one or more stereoisomer. Isomers can be isolated from mixtures by methods known to those skilled in the art, including chiral high pressure liquid chromatography (HPLC) and the formation and crystallization of chiral salts; or preferred isomers can be prepared by asymmetric syntheses. See, for example, Jacques et al., Enantiomers, Racemates and Resolutions (Wiley Interscience, New York, 1981); Wilen et al., Tetrahedron 33:2725 (1977); Eliel, E. L. Stereochemistry of Carbon Compounds (McGraw-Hill, NY, 1962); and Wilen, S.H. Tables of Resolving Agents and Optical Resolutions p. 268 (E. L. Eliel, Ed., Univ. of Notre Dame Press, Notre Dame, Ind. 1972). Compounds may exist as individual isomers substantially free of other isomers, and alternatively, as mixtures of various isomers.

When a range of values is listed, it is intended to encompass each value and sub-range within the range. For example “C₁₋₆ alkyl” is intended to encompass, C₁, C₂, C₃, C₄, C₅, C₆, C₁₋₆, C₁₋₅, C₁₋₄, C₁₋₃, C₁₋₂, C₂₋₆, C₂₋₅, C₂₋₄, C₂₋₃, C₃₋₆, C₃₋₅, C₃₋₄, C₄₋₆, C₄₋₅, and C₅₋₆ alkyl.

As used herein, “alkyl” refers to a radical of a straight-chain or branched saturated hydrocarbon group having from 1 to 10 carbon atoms (“C₁₋₁₀ alkyl”). In some embodiments, an alkyl group has 1 to 9 carbon atoms (“C₁₋₉ alkyl”). In some embodiments, an alkyl group has 1 to 8 carbon atoms (“C₁₋₈ alkyl”). In some embodiments, an alkyl group has 1 to 7 carbon atoms (“C₁₋₇ alkyl”). In some embodiments, an alkyl group has 1 to 6 carbon atoms (“C₁₋₆ alkyl”). In some embodiments, an alkyl group has 1 to 5 carbon atoms (“C₁₋₅ alkyl”). In some embodiments, an alkyl group has 1 to 4 carbon atoms (“C₁₋₄ alkyl”). In some embodiments, an alkyl group has 1 to 3 carbon atoms (“C₁₋₃ alkyl”). In some embodiments, an alkyl group has 1 to 2 carbon atoms (“C₁₋₂ alkyl”). In some embodiments, an alkyl group has 1 carbon atom (“C1 alkyl”). In some embodiments, an alkyl group has 2 to 6 carbon atoms (“C₂₋₆ alkyl”). Examples of C₁₋₆ alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (C₅), 3-pentanyl (C5), amyl (C5), neopentyl (C₅), 3-methyl-2-butanyl (C₅), tertiary amyl (C₅), and n-hexyl (C6). Additional examples of alkyl groups include n-heptyl (C₇), n-octyl (C₈) and the like. Unless otherwise specified, each instance of an alkyl group is independently unsubstituted (an “unsubstituted alkyl”) or substituted (a “substituted alkyl”) with one or more substituents. In certain embodiments, the alkyl group is an unsubstituted C₁₋₁₀ alkyl (e.g., —CH₃). In certain embodiments, the alkyl group is a substituted C₁₋₁₀ alkyl.

The term “heteroalkyl” refers to an alkyl group, which further includes at least one heteroatom (e.g., 1, 2, 3, or 4 heteroatoms) selected from oxygen, nitrogen, or sulfur within (i.e., inserted between adjacent carbon atoms of) and/or placed at one or more terminal position(s) of the parent chain. In certain embodiments, a heteroalkyl group refers to a saturated group having from 1 to 10 carbon atoms and 1 or more heteroatoms within the parent chain (“heteroC₁₋₁₀ alkyl”). In some embodiments, a heteroalkyl group is a saturated group having 1 to 9 carbon atoms and 1 or more heteroatoms within the parent chain (“heteroC₁₋₉ alkyl”). In some embodiments, a heteroalkyl group is a saturated group having 1 to 8 carbon atoms and 1 or more heteroatoms within the parent chain (“heteroC₁₋₈ alkyl”). In some embodiments, a heteroalkyl group is a saturated group having 1 to 7 carbon atoms and 1 or more heteroatoms within the parent chain (“heteroC₁₋₇ alkyl”). In some embodiments, a heteroalkyl group is a saturated group having 1 to 6 carbon atoms and 1 or more heteroatoms within the parent chain (“heteroC₁₋₆ alkyl”). In some embodiments, a heteroalkyl group is a saturated group having 1 to 5 carbon atoms and 1 or 2 heteroatoms within the parent chain (“heteroC₁₋₅ alkyl”). In some embodiments, a heteroalkyl group is a saturated group having 1 to 4 carbon atoms and for 2 heteroatoms within the parent chain (“heteroC₁₋₄ alkyl”). In some embodiments, a heteroalkyl group is a saturated group having 1 to 3 carbon atoms and 1 heteroatom within the parent chain (“heteroC₁₋₃ alkyl”). In some embodiments, a heteroalkyl group is a saturated group having 1 to 2 carbon atoms and 1 heteroatom within the parent chain (“heteroC₁₋₂ alkyl”). In some embodiments, a heteroalkyl group is a saturated group having 1 carbon atom and 1 heteroatom (“heteroC₁ alkyl”). In some embodiments, a heteroalkyl group is a saturated group having 2 to 6 carbon atoms and 1 or 2 heteroatoms within the parent chain (“heteroC₂₋₆ alkyl”). Unless otherwise specified, each instance of a heteroalkyl group is independently unsubstituted (an “unsubstituted heteroalkyl”) or substituted (a “substituted heteroalkyl”) with one or more substituents. In certain embodiments, the heteroalkyl group is an unsubstituted heteroC₁₋₁₀ alkyl. In certain embodiments, the heteroalkyl group is a substituted heteroC₁₋₁₀ alkyl.

The term “alkenyl” refers to a radical of a straight-chain or branched hydrocarbon group having from 2 to 10 carbon atoms and one or more carbon-carbon double bonds (e.g., 1, 2, 3, or 4 double bonds). In some embodiments, an alkenyl group has 2 to 9 carbon atoms (“C₂₋₉ alkenyl”). In some embodiments, an alkenyl group has 2 to 8 carbon atoms (“C₂₋₈ alkenyl”). In some embodiments, an alkenyl group has 2 to 7 carbon atoms (“C₂₋₇ alkenyl”). In some embodiments, an alkenyl group has 2 to 6 carbon atoms (“C₂₋₆ alkenyl”). In some embodiments, an alkenyl group has 2 to 5 carbon atoms (“C₂₋₅ alkenyl”). In some embodiments, an alkenyl group has 2 to 4 carbon atoms (“C₂₋₄ alkenyl”). In some embodiments, an alkenyl group has 2 to 3 carbon atoms (“C₂₋₃ alkenyl”). In some embodiments, an alkenyl group has 2 carbon atoms (“C₂ alkenyl”). The one or more carbon-carbon double bonds can be internal (such as in 2-butenyl) or terminal (such as in 1-butenyl). Examples of C₂₋₄ alkenyl groups include ethenyl (C₂), 1-propenyl (C₃), 2-propenyl (C₃), 1-butenyl (C₄), 2-butenyl (C₄), butadienyl (C₄), and the like. Examples of C₂₋₆ alkenyl groups include the aforementioned C₂₋₄ alkenyl groups as well as pentenyl (C₅), pentadienyl (C₅), hexenyl (C₆), and the like. Additional examples of alkenyl include heptenyl (C₇), octenyl (C₈), octatrienyl (C₈), and the like. Unless otherwise specified, each instance of an alkenyl group is independently unsubstituted (an “unsubstituted alkenyl”) or substituted (a “substituted alkenyl”) with one or more substituents. In certain embodiments, the alkenyl group is an unsubstituted C₂₋₁₀ alkenyl. In certain embodiments, the alkenyl group is a substituted C₂₋₁₀ alkenyl. In an alkenyl group, a C═C double bond for which the stereochemistry is not specified (e.g., —CH═CHCH₃ or

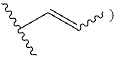

may be an (E)- or (Z)-double bond.

The term “heteroalkenyl” refers to an alkenyl group, which further includes at least one heteroatom (e.g., 1, 2, 3, or 4 heteroatoms) selected from oxygen, nitrogen, or sulfur within (i.e., inserted between adjacent carbon atoms of) and/or placed at one or more terminal position(s) of the parent chain. In certain embodiments, a heteroalkenyl group refers to a group having from 2 to 10 carbon atoms, at least one double bond, and 1 or more heteroatoms within the parent chain (“heteroC₂₋₁₀ alkenyl”). In some embodiments, a heteroalkenyl group has 2 to 9 carbon atoms at least one double bond, and 1 or more heteroatoms within the parent chain (“heteroC₂₋₉ alkenyl”). In some embodiments, a heteroalkenyl group has 2 to 8 carbon atoms, at least one double bond, and 1 or more heteroatoms within the parent chain (“heteroC₂₋₈ alkenyl”). In some embodiments, a heteroalkenyl group has 2 to 7 carbon atoms, at least one double bond, and 1 or more heteroatoms within the parent chain (“heteroC₃₋₇ alkenyl”). In some embodiments, a heteroalkenyl group has 2 to 6 carbon atoms, at least one double bond, and 1 or more heteroatoms within the parent chain (“heteroC₂₋₆ alkenyl”). In some embodiments, a heteroalkenyl group has 2 to 5 carbon atoms, at least one double bond, and 1 or 2 heteroatoms within the parent chain (“heteroC₂₋₅ alkenyl”). In some embodiments, a heteroalkenyl group has 2 to 4 carbon atoms, at least one double bond, and for 2 heteroatoms within the parent chain (“heteroC₂₋₄ alkenyl”). In some embodiments, a heteroalkenyl group has 2 to 3 carbon atoms, at least one double bond, and 1 heteroatom within the parent chain (“heteroC₂₋₃ alkenyl”). In some embodiments, a heteroalkenyl group has 2 to 6 carbon atoms, at least one double bond, and 1 or 2 heteroatoms within the parent chain (“heteroC₂₋₆ alkenyl”). Unless otherwise specified, each instance of a heteroalkenyl group is independently unsubstituted (an “unsubstituted heteroalkenyl”) or substituted (a “substituted heteroalkenyl”) with one or more substituents. In certain embodiments, the heteroalkenyl group is an unsubstituted heteroC₂₋₁₀ alkenyl. In certain embodiments, the heteroalkenyl group is a substituted heteroC₂₋₁₀ alkenyl.

The term “alkynyl” refers to a radical of a straight-chain or branched hydrocarbon group having from 2 to 10 carbon atoms and one or more carbon-carbon triple bonds (e.g., 1, 2, 3, or 4 triple bonds) (“C₂₋₁₀ alkynyl”). In some embodiments, an alkynyl group has 2 to 9 carbon atoms (“C₂₋₉ alkynyl”). In some embodiments, an alkynyl group has 2 to 8 carbon atoms (“C₂₋₈ alkynyl”). In some embodiments, an alkynyl group has 2 to 7 carbon atoms (“C₂₋₆ alkynyl”). In some embodiments, an alkynyl group has 2 to 6 carbon atoms (“C₂₋₅ alkynyl”). In some embodiments, an alkynyl group has 2 to 5 carbon atoms (“C₂₋₅ alkynyl”). In some embodiments, an alkynyl group has 2 to 4 carbon atoms (“C₂₋₄ alkynyl”). In some embodiments, an alkynyl group has 2 to 3 carbon atoms (“C₂₋₃ alkynyl”). In some embodiments, an alkynyl group has 2 carbon atoms (“C₂ alkynyl”). The one or more carbon-carbon triple bonds can be internal (such as in 2-butynyl) or terminal (such as in 1-butynyl). Examples of C₂₋₄ alkynyl groups include, without limitation, ethynyl (C₂), 1-propynyl (C₃), 2-propynyl (C₃), 1-butynyl (C₄), 2-butynyl (C₄), and the like. Examples of C₂₋₆ alkenyl groups include the aforementioned C₂₋₄ alkynyl groups as well as pentynyl (C₅), hexynyl (C₆), and the like. Additional examples of alkynyl include heptynyl (C₇), octynyl (C₈), and the like. Unless otherwise specified, each instance of an alkynyl group is independently unsubstituted (an “unsubstituted alkynyl”) or substituted (a “substituted alkynyl”) with one or more substituents. In certain embodiments, the alkynyl group is an unsubstituted C₂₋₁₀ alkynyl. In certain embodiments, the alkynyl group is a substituted C₂₋₁₀ alkynyl.

The term “heteroalkynyl” refers to an alkynyl group, which further includes at least one heteroatom (e.g., 1, 2, 3, or 4 heteroatoms) selected from oxygen, nitrogen, or sulfur within (i.e., inserted between adjacent carbon atoms of) and/or placed at one or more terminal position(s) of the parent chain. In certain embodiments, a heteroalkynyl group refers to a group having from 2 to 10 carbon atoms, at least one triple bond, and 1 or more heteroatoms within the parent chain (“heteroC₂₋₁₀ alkynyl”). In some embodiments, a heteroalkynyl group has 2 to 9 carbon atoms, at least one triple bond, and 1 or more heteroatoms within the parent chain (“heteroC₂₋₉ alkynyl”). In some embodiments, a heteroalkynyl group has 2 to 8 carbon atoms, at least one triple bond, and 1 or more heteroatoms within the parent chain (“heteroC₂₋₈ alkynyl”). In some embodiments, a heteroalkynyl group has 2 to 7 carbon atoms, at least one triple bond, and 1 or more heteroatoms within the parent chain (“heteroC₂₋₇ alkynyl”). In some embodiments, a heteroalkynyl group has 2 to 6 carbon atoms, at least one triple bond, and 1 or more heteroatoms within the parent chain (“heteroC₂₋₆ alkynyl”). In some embodiments, a heteroalkynyl group has 2 to 5 carbon atoms, at least one triple bond, and 1 or 2 heteroatoms within the parent chain (“heteroC₂₋₅ alkynyl”). In some embodiments, a heteroalkynyl group has 2 to 4 carbon atoms, at least one triple bond, and for 2 heteroatoms within the parent chain (“heteroC₂₋₄ alkynyl”). In some embodiments, a heteroalkynyl group has 2 to 3 carbon atoms, at least one triple bond, and 1 heteroatom within the parent chain (“heteroC₂₋₃ alkynyl”). In some embodiments, a heteroalkynyl group has 2 to 6 carbon atoms, at least one triple bond, and 1 or 2 heteroatoms within the parent chain (“heteroC₂₋₆ alkynyl”). Unless otherwise specified, each instance of a heteroalkynyl group is independently unsubstituted (an “unsubstituted heteroalkynyl”) or substituted (a “substituted heteroalkynyl”) with one or more substituents. In certain embodiments, the heteroalkynyl group is an unsubstituted heteroC₂₋₁₀ alkynyl. In certain embodiments, the heteroalkynyl group is a substituted heteroC₂₋₁₀ alkynyl.

The term “carbocyclyl” or “carbocyclic” refers to a radical of a non-aromatic cyclic hydrocarbon group having from 3 to 14 ring carbon atoms (“C₃₋₁₄ carbocyclyl”) and zero heteroatoms in the non-aromatic ring system. In some embodiments, a carbocyclyl group has 3 to 10 ring carbon atoms (“C₃₋₁₀ carbocyclyl”). In some embodiments, a carbocyclyl group has 3 to 8 ring carbon atoms (“C₃₋₈ carbocyclyl”). In some embodiments, a carbocyclyl group has 3 to 7 ring carbon atoms (“C₃₋₇ carbocyclyl”). In some embodiments, a carbocyclyl group has 3 to 6 ring carbon atoms (“C₃₋₆ carbocyclyl”). In some embodiments, a carbocyclyl group has 4 to 6 ring carbon atoms (“C₄₋₆ carbocyclyl”). In some embodiments, a carbocyclyl group has 5 to 6 ring carbon atoms (“C₅₋₆ carbocyclyl”). In some embodiments, a carbocyclyl group has 5 to 10 ring carbon atoms (“C₅₋₁₀ carbocyclyl”). Exemplary C₃₋₆ carbocyclyl groups include, without limitation, cyclopropyl (C₃), cyclopropenyl (C₃), cyclobutyl (C₄), cyclobutenyl (C₄), cyclopentyl (C₅), cyclopentenyl (C₅), cyclohexyl (C₆), cyclohexenyl (C₆), cyclohexadienyl (C₆), and the like. Exemplary C₃₋₈ carbocyclyl groups include, without limitation, the aforementioned C₃₋₆ carbocyclyl groups as well as cycloheptyl (C₇), cycloheptenyl (C₇), cycloheptadienyl (C₇), cycloheptatrienyl (C₇), cyclooctyl (C₈), cyclooctenyl (C₈), bicyclo[2.2.1]heptanyl (C₇), bicyclo[2.2.2]octanyl (C₈), and the like. Exemplary C₃₋₁₀ carbocyclyl groups include, without limitation, the aforementioned C₃₋₈ carbocyclyl groups as well as cyclononyl (C₉), cyclononenyl (C₉), cyclodecyl (C₁₀), cyclodecenyl (C₁₀), octahydro-1H-indenyl (C₉), decahydronaphthalenyl (C₁₀), spiro[4.5]decanyl (C₁₀), and the like. As the foregoing examples illustrate, in certain embodiments, the carbocyclyl group is either monocyclic (“monocyclic carbocyclyl”) or polycyclic (e.g., containing a fused, bridged or spiro ring system such as a bicyclic system (“bicyclic carbocyclyl”) or tricyclic system (“tricyclic carbocyclyl”)) and can be saturated or can contain one or more carbon-carbon double or triple bonds. “Carbocyclyl” also includes ring systems wherein the carbocyclyl ring, as defined above, is fused with one or more aryl or heteroaryl groups wherein the point of attachment is on the carbocyclyl ring, and in such instances, the number of carbons continue to designate the number of carbons in the carbocyclic ring system. Unless otherwise specified, each instance of a carbocyclyl group is independently unsubstituted (an “unsubstituted carbocyclyl”) or substituted (a “substituted carbocyclyl”) with one or more substituents. In certain embodiments, the carbocyclyl group is an unsubstituted C₃₋₁₄ carbocyclyl. In certain embodiments, the carbocyclyl group is a substituted C₃₋₁₄ carbocyclyl.

In some embodiments, “carbocyclyl” is a monocyclic, saturated carbocyclyl group having from 3 to 14 ring carbon atoms (“C₃₋₁₄ cycloalkyl”). In some embodiments, a cycloalkyl group has 3 to 10 ring carbon atoms (“C₃₋₁₀ cycloalkyl”). In some embodiments, a cycloalkyl group has 3 to 8 ring carbon atoms (“C₃₋₈ cycloalkyl”). In some embodiments, a cycloalkyl group has 3 to 6 ring carbon atoms (“C₃₋₆ cycloalkyl”). In some embodiments, a cycloalkyl group has 4 to 6 ring carbon atoms (“C₄₋₆ cycloalkyl”). In some embodiments, a cycloalkyl group has 5 to 6 ring carbon atoms (“C₅₋₆ cycloalkyl”). In some embodiments, a cycloalkyl group has 5 to 10 ring carbon atoms (“C₅₋₁₀ cycloalkyl”). Examples of C₅₋₆ cycloalkyl groups include cyclopentyl (C₅) and cyclohexyl (C₅). Examples of C₃₋₆ cycloalkyl groups include the aforementioned C₅₋₆ cycloalkyl groups as well as cyclopropyl (C₃) and cyclobutyl (C₄). Examples of C₃₋₈ cycloalkyl groups include the aforementioned C₃₋₆ cycloalkyl groups as well as cycloheptyl (C₇) and cyclooctyl (C₈). Unless otherwise specified, each instance of a cycloalkyl group is independently unsubstituted (an “unsubstituted cycloalkyl”) or substituted (a “substituted cycloalkyl”) with one or more substituents. In certain embodiments, the cycloalkyl group is an unsubstituted C₃₋₁₄ cycloalkyl. In certain embodiments, the cycloalkyl group is a substituted C₃₋₁₄ cycloalkyl. As used herein, “heterocyclyl” or “heterocyclic” refers to a radical of a 3to 14membered non-aromatic ring system having ring carbon atoms and 1 to 4 ring heteroatoms, wherein each heteroatom is independently selected from nitrogen, oxygen, and sulfur (“3-14 membered heterocyclyl”). In heterocyclyl groups that contain one or more nitrogen atoms, the point of attachment can be a carbon or nitrogen atom, as valency permits. A heterocyclyl group can either be monocyclic (“monocyclic heterocyclyl”) or polycyclic (e.g., a fused, bridged or spiro ring system such as a bicyclic system (“bicyclic heterocyclyl”) or tricyclic system (“tricyclic heterocyclyl”)), and can be saturated or can contain one or more carboncarbon double or triple bonds. Heterocyclyl polycyclic ring systems can include one or more heteroatoms in one or both rings. “Heterocyclyl” also includes ring systems wherein the heterocyclyl ring, as defined above, is fused with one or more carbocyclyl groups wherein the point of attachment is either on the carbocyclyl or heterocyclyl ring, or ring systems wherein the heterocyclyl ring, as defined above, is fused with one or more aryl or heteroaryl groups, wherein the point of attachment is on the heterocyclyl ring, and in such instances, the number of ring members continue to designate the number of ring members in the heterocyclyl ring system. Unless otherwise specified, each instance of heterocyclyl is independently unsubstituted (an “unsubstituted heterocyclyl”) or substituted (a “substituted heterocyclyl”) with one or more substituents. In certain embodiments, the heterocyclyl group is an unsubstituted 3-14 membered heterocyclyl. In certain embodiments, the heterocyclyl group is a substituted 3-14 membered heterocyclyl.

In some embodiments, a heterocyclyl group is a 5-10 membered nonaromatic ring system having ring carbon atoms and 1-4 ring heteroatoms, wherein each heteroatom is independently selected from nitrogen, oxygen, and sulfur (“5-10 membered heterocyclyl”). In some embodiments, a heterocyclyl group is a 5-8 membered nonaromatic ring system having ring carbon atoms and 1-4 ring heteroatoms, wherein each heteroatom is independently selected from nitrogen, oxygen, and sulfur (“5-8 membered heterocyclyl”). In some embodiments, a heterocyclyl group is a 5-6 membered nonaromatic ring system having ring carbon atoms and 1-4 ring heteroatoms, wherein each heteroatom is independently selected from nitrogen, oxygen, and sulfur (“5-6 membered heterocyclyl”). In some embodiments, the 5-6 membered heterocyclyl has 1-3 ring heteroatoms selected from nitrogen, oxygen, and sulfur. In some embodiments, the 5-6 membered heterocyclyl has 1-2 ring heteroatoms selected from nitrogen, oxygen, and sulfur. In some embodiments, the 5-6 membered heterocyclyl has 1 ring heteroatom selected from nitrogen, oxygen, and sulfur.

Exemplary 3—membered heterocyclyl groups containing 1 heteroatom include, without limitation, azirdinyl, oxiranyl, thiorenyl. Exemplary 4—membered heterocyclyl groups containing 1 heteroatom include, without limitation, azetidinyl, oxetanyl and thietanyl. Exemplary 5—membered heterocyclyl groups containing 1 heteroatom include, without limitation, tetrahydrofuranyl, dihydrofuranyl, tetrahydrothiophenyl, dihydrothiophenyl, pyrrolidinyl, dihydropyrrolyl and pyrrolyl-2,5-dione. Exemplary 5—membered heterocyclyl groups containing 2 heteroatoms include, without limitation, dioxolanyl, oxathiolanyl and dithiolanyl. Exemplary 5—membered heterocyclyl groups containing 3 heteroatoms include, without limitation, triazolinyl, oxadiazolinyl, and thiadiazolinyl. Exemplary 6—membered heterocyclyl groups containing 1 heteroatom include, without limitation, piperidinyl, tetrahydropyranyl, dihydropyridinyl, and thianyl. Exemplary 6—membered heterocyclyl groups containing 2 heteroatoms include, without limitation, piperazinyl, morpholinyl, dithianyl, dioxanyl. Exemplary 6—membered heterocyclyl groups containing 3 heteroatoms include, without limitation, triazinyl. Exemplary 7—membered heterocyclyl groups containing 1 heteroatom include, without limitation, azepanyl, oxepanyl and thiepanyl. Exemplary 8—membered heterocyclyl groups containing 1 heteroatom include, without limitation, azocanyl, oxecanyl and thiocanyl. Exemplary bicyclic heterocyclyl groups include, without limitation, indolinyl, isoindolinyl, dihydrobenzofuranyl, dihydrobenzothienyl, tetra-ihydro-ibenzo-ithienyl, tetrahydrobenzofuranyl, tetrahydroindolyl, tetrahydroquinolinyl, tetrahydroisoquinolinyl, decahydroquinolinyl, decahydroisoquinolinyl, octahydrochromenyl, octahydroisochromenyl, decahydronaphthyridinyl, decahydro-1,8-naphthyridinyl, octahydropyrrolo[3,2-b]pyrrole, indolinyl, phthalimidyl, naphthalimidyl, chromanyl, chromenyl, 1H-benzo[e][1,4]diazepinyl, 1,4,5,7-tetrahydropyrano[3,4-b]pyrrolyl, 5,6-dihydro-4H-furo[3,2-b]pyrrolyl, 6,7-dihydro-5H-furo[3,2-b]pyranyl, 5,7-dihydro-4H-thieno[2,3-c]pyranyl, 2,3-dihydro-1H-pyrrolo[2,3-b]pyridinyl, 2,3-dihydrofuro[2,3-b]pyridinyl, 4,5,6,7-tetrahydro-1H-pyrrolo-[2,3-b]pyridinyl, 4,5,6,7-tetrahydrofuro[3,2-c]pyridinyl, 4,5,6,7-tetrahydrothieno[3,2-b]pyridinyl, 1,2,3,4-tetrahydro-1,6-naphthyridinyl, and the like.

As used herein, “aryl” refers to a radical of a monocyclic or polycyclic (e.g., bicyclic or tricyclic) 4n+2 aromatic ring system (e.g., having 6, 10, or 14 π electrons shared in a cyclic array) having 6-14 ring carbon atoms and zero heteroatoms provided in the aromatic ring system (“C₆₋₁₄ aryl”). In some embodiments, an aryl group has 6 ring carbon atoms (“C₆ aryl”; e.g., phenyl). In some embodiments, an aryl group has 10 ring carbon atoms (“C₁₀ aryl”; e.g., naphthyl such as 1-naphthyl and 2-naphthyl). In some embodiments, an aryl group has 14 ring carbon atoms (“C₁₄ aryl”; e.g., anthracyl). “Aryl” also includes ring systems wherein the aryl ring, as defined above, is fused with one or more carbocyclyl or heterocyclyl groups wherein the radical or point of attachment is on the aryl ring, and in such instances, the number of carbon atoms continue to designate the number of carbon atoms in the aryl ring system. Unless otherwise specified, each instance of an aryl group is independently unsubstituted (an “unsubstituted aryl”) or substituted (a “substituted aryl”) with one or more substituents. In certain embodiments, the aryl group is an unsubstituted C₆₋₁₄ aryl. In certain embodiments, the aryl group is a substituted C₆₋₁₄ aryl.

As used herein, “heteroaryl” refers to a radical of a 5-14 membered monocyclic or polycyclic (e.g., bicyclic, tricyclic) 4n+2 aromatic ring system (e.g., having 6,10, or 14 π electrons shared in a cyclic array) having ring carbon atoms and 1-4 ring heteroatoms provided in the aromatic ring system, wherein each heteroatom is independently selected from nitrogen, oxygen and sulfur (“5-14 membered heteroaryl”). In heteroaryl groups that contain one or more nitrogen atoms, the point of attachment can be a carbon or nitrogen atom, as valency permits. Heteroaryl polycyclic ring systems can include one or more heteroatoms in one or both rings. “Heteroaryl” includes ring systems wherein the heteroaryl ring, as defined above, is fused with one or more carbocyclyl or heterocyclyl groups wherein the point of attachment is on the heteroaryl ring, and in such instances, the number of ring members continue to designate the number of ring members in the heteroaryl ring system. “Heteroaryl” also includes ring systems wherein the heteroaryl ring, as defined above, is fused with one or more aryl groups wherein the point of attachment is either on the aryl or heteroaryl ring, and in such instances, the number of ring members designates the number of ring members in the fused polycyclic (aryl/heteroaryl) ring system. Polycyclic heteroaryl groups wherein one ring does not contain a heteroatom (e.g., indolyl, quinolinyl, carbazolyl, and the like) the point of attachment can be on either ring, i.e., either the ring bearing a heteroatom (e.g., 2-indolyl) or the ring that does not contain a heteroatom (e.g., 5-indolyl).

In some embodiments, a heteroaryl group is a 5-10 membered aromatic ring system having ring carbon atoms and 1-4 ring heteroatoms provided in the aromatic ring system, wherein each heteroatom is independently selected from nitrogen, oxygen, and sulfur (“5-10 membered heteroaryl”). In some embodiments, a heteroaryl group is a 5-8 membered aromatic ring system having ring carbon atoms and 1-4 ring heteroatoms provided in the aromatic ring system, wherein each heteroatom is independently selected from nitrogen, oxygen, and sulfur (“5-8 membered heteroaryl”). In some embodiments, a heteroaryl group is a 5-6 membered aromatic ring system having ring carbon atoms and 1-4 ring heteroatoms provided in the aromatic ring system, wherein each heteroatom is independently selected from nitrogen, oxygen, and sulfur (“5-6 membered heteroaryl”). In some embodiments, the 5-6 membered heteroaryl has 1-3 ring heteroatoms selected from nitrogen, oxygen, and sulfur. In some embodiments, the 5-6 membered heteroaryl has 1-2 ring heteroatoms selected from nitrogen, oxygen, and sulfur. In some embodiments, the 5-6 membered heteroaryl has 1 ring heteroatom selected from nitrogen, oxygen, and sulfur. Unless otherwise specified, each instance of a heteroaryl group is independently unsubstituted (an “unsubstituted heteroaryl”) or substituted (a “substituted heteroaryl”) with one or more substituents. In certain embodiments, the heteroaryl group is an unsubstituted 5-14 membered heteroaryl. In certain embodiments, the heteroaryl group is a substituted 5-14 membered heteroaryl.

Exemplary 5membered heteroaryl groups containing 1 heteroatom include, without limitation, pyrrolyl, furanyl and thiophenyl. Exemplary 5membered heteroaryl groups containing 2 heteroatoms include, without limitation, imidazolyl, pyrazolyl, oxazolyl, isoxazolyl, thiazolyl, and isothiazolyl. Exemplary 5—membered heteroaryl groups containing 3 heteroatoms include, without limitation, triazolyl, oxadiazolyl, and thiadiazolyl. Exemplary 5—membered heteroaryl groups containing 4 heteroatoms include, without limitation, tetrazolyl. Exemplary 6—membered heteroaryl groups containing 1 heteroatom include, without limitation, pyridinyl. Exemplary 6—membered heteroaryl groups containing 2 heteroatoms include, without limitation, pyridazinyl, pyrimidinyl, and pyrazinyl. Exemplary 6—membered heteroaryl groups containing 3 or 4 heteroatoms include, without limitation, triazinyl and tetrazinyl, respectively. Exemplary 7—membered heteroaryl groups containing 1 heteroatom include, without limitation, azepinyl, oxepinyl, and thiepinyl. Exemplary 5,6-bicyclic heteroaryl groups include, without limitation, indolyl, isoindolyl, indazolyl, benzotriazolyl, benzothiophenyl, isobenzothiophenyl, benzofuranyl, benzoisofuranyl, benzimidazolyl, benzoxazolyl, benzisoxazolyl, benzoxadiazolyl, benzthiazolyl, benzisothiazolyl, benzthiadiazolyl, indolizinyl, and purinyl. Exemplary 6,6—bicyclic heteroaryl groups include, without limitation, naphthyridinyl, pteridinyl, quinolinyl, isoquinolinyl, cinnolinyl, quinoxalinyl, phthalazinyl, and quinazolinyl. Exemplary tricyclic heteroaryl groups include, without limitation, phenanthridinyl, dibenzofuranyl, carbazolyl, acridinyl, phenothiazinyl, phenoxazinyl and phenazinyl.

As used herein, the term “partially unsaturated” refers to a ring moiety that includes at least one double or triple bond. The term “partially unsaturated” is intended to encompass rings having multiple sites of unsaturation, but is not intended to include aromatic groups (e.g., aryl or heteroaryl moieties) as herein defined.

As used herein, the term “saturated” refers to a ring moiety that does not contain a double or triple bond, i.e., the ring contains all single bonds.

Affixing the suffix “-ene” to a group indicates the group is a divalent moiety, e.g., alkylene is the divalent moiety of alkyl, alkenylene is the divalent moiety of alkenyl, alkynylene is the divalent moiety of alkynyl, heteroalkylene is the divalent moiety of heteroalkyl, heteroalkenylene is the divalent moiety of heteroalkenyl, heteroalkynylene is the divalent moiety of heteroalkynyl, carbocyclylene is the divalent moiety of carbocyclyl, heterocyclylene is the divalent moiety of heterocyclyl, arylene is the divalent moiety of aryl, and heteroarylene is the divalent moiety of heteroaryl.

As understood from the above, alkyl, alkenyl, alkynyl, heteroalkyl, heteroalkenyl, heteroalkynyl, carbocyclyl, heterocyclyl, aryl, and heteroaryl groups, as described herein, are, in certain embodiments, optionally substituted. Optionally substituted refers to a group which may be substituted or unsubstituted (e.g., “substituted” or “unsubstituted” alkyl, “substituted” or “unsubstituted” alkenyl, “substituted” or “unsubstituted” alkynyl, “substituted” or “unsubstituted” heteroalkyl, “substituted” or “unsubstituted” heteroalkenyl, “substituted” or “unsubstituted” heteroalkynyl, “substituted” or “unsubstituted” carbocyclyl, “substituted” or “unsubstituted” heterocyclyl, “substituted” or “unsubstituted” aryl or “substituted” or “unsubstituted” heteroaryl group). In general, the term “substituted”, whether preceded by the term “optionally” or not, means that at least one hydrogen present on a group (e.g., a carbon or nitrogen atom) is replaced with a permissible substituent, e.g., a substituent which upon substitution results in a stable compound, e.g., a compound which does not spontaneously undergo transformation such as by rearrangement, cyclization, elimination, or other reaction. Unless otherwise indicated, a “substituted” group has a substituent at one or more substitutable positions of the group, and when more than one position in any given structure is substituted, the substituent is either the same or different at each position. The term “substituted” is contemplated to include substitution with all permissible substituents of organic compounds, any of the substituents described herein that results in the formation of a stable compound. The present invention contemplates any and all such combinations in order to arrive at a stable compound. For purposes of this invention, heteroatoms such as nitrogen may have hydrogen substituents and/or any suitable substituent as described herein which satisfy the valencies of the heteroatoms and results in the formation of a stable moiety.

Exemplary carbon atom substituents include, but are not limited to, halogen, —CN, —NO₂, —N₃, —SO₂H, —SO₃H, —OH, —OR^{aa}, —ON(R^{bb})₂, —N(R^{bb})₂, —N(R^{bb})₃⁺X⁻, −N(OR^{cc})R^{bb}, —SH, —SR^{aa}, —SSR^{cc}, —C(═O)R^{aa}, —CO₂H, —CHO, —C(OR^{cc})₃, —CO₂R^{aa}, —OC(═O)R^{aa}, —OCO₂R^{aa}, —C(═O)N(R^{bb})₂, —OC(═O)N(R^{bb})₂, —NR^{bb}C(═O)R^{aa}, —NR^{bb}CO₂R^{aa}, —NR^{bb}C(═O)N(R^{bb})₂, —C(═NR^{bb})R^{aa}, —C(═NR^{bb})OR^{aa}, —OC(═NR^{bb})R^{aa}, —OC(═NR^{bb})OR^{aa}, —C(═NR^{bb})N(R^{bb})₂, —OC(═NR^{bb})N(R^{bb})₂, —NR^{bb}C(═NR^{bb})N(R^{bb})₂, —C (═O)NR^{bb}SO₂R^{aa}, —NR^{bb}SO₂R^{aa}, —SO₂N(R^{bb})₂, —SO₂R^{aa}, —SO₂OR^{aa}, —OSO₂R^{aa}, —S (═O)R^{aa}, —OS(═O)R^{aa}, —Si(R^{aa})₃, —OSi(R^{aa})₃—C(═S)N(R^{bb})₂, —C(═O)SR^{aa}, —C(═S)SR^{aa}, —SC(═S)SR^{aa}, —SC(═O)SR^{aa}, —OC(═O)SR^{aa}, —SC(═O)OR^{aa}, —SC(═O)R^{aa}, —P(═O)(R^{aa})₂, —P(═O)(OR^{cc})₂, —OP(═O)(R^{aa})₂, —OP(═O)(OR^{cc})₂, —P(═O)(N(R^{bb})₂)₂, —OP(═O)(N(R^{bb})₂)₂, —NR^{bb}P(═O)(R^{aa})₂, —NR^{bb}P(═O)(OR^{cc})₂, —NR^{bb}P(═O)(N(R^{bb})₂)₂, —P(R^{cc})₂, —P(OR^{cc})₂, —P(R^{cc})₃⁺X⁻, —P(OR^{cc})₃⁺X⁻, —P(R^{cc})₄, —P(OR^{cc})₄, —OP(R^{cc})₂, —OP(R^{cc})₃⁺X⁻, —OP(OR^{cc})₂, —OP(OR^{cc})₃⁺X⁻, —OP(R^{cc})₄, —OP(OR^{cc})₄, -B(R^{aa})₂, -B(OR^{cc})₂, -BR^{aa}(OR^{cc}), C₁₋₁₀ alkyl, C₁₋₁₀ perhaloalkyl, C₂₋₁₀ alkenyl, C₂₋₁₀ alkynyl, heteroC₁₋₁₀ alkyl, heteroC₂₋₁₀ alkenyl, heteroC₂₋₁₀ alkynyl, C₃₋₁₀ carbocyclyl, 3-14 membered heterocyclyl, C₆₋₁₄ aryl, and 5-14 membered heteroaryl, wherein each alkyl, alkenyl, alkynyl, heteroalkyl, heteroalkenyl, heteroalkynyl, carbocyclyl, heterocyclyl, aryl, and heteroaryl is independently substituted with 0, 1, 2, 3, 4, or 5 R^{dd} groups; wherein X⁻ is a counterion;

or two geminal hydrogens on a carbon atom are replaced with the group ═O, ═S, ═NN(R^{bb})₂, ═NNR^{bb}C(═O)R^{aa}, ═NNR^{bb}C(═O)OR^{aa}, ═NNR^{bb}S (═O)₂R^{aa}, ═NR^{bb} , or ═NOR^{cc};

each instance of R^{aa} is, independently, selected from C₁₋₁₀ alkyl, C₁₋₁₀ perhaloalkyl, C₂₋₁₀ alkenyl, C₂₋₁₀ alkynyl, heteroC₁₋₁₀ alkyl, heteroC₂₋₁₀alkenyl, heteroC₂₋₁₀ alkynyl, C₃₋₁₀ carbocyclyl, 3-14 membered heterocyclyl, C6_14 aryl, and 5-14 membered heteroaryl, or two Raa groups are joined to form a 3-14 membered heterocyclyl or 5-14 membered heteroaryl ring, wherein each alkyl, alkenyl, alkynyl, heteroalkyl, heteroalkenyl, heteroalkynyl, carbocyclyl, heterocyclyl, aryl, and heteroaryl is independently substituted with 0, 1, 2, 3, 4, or 5 R^{dd} groups;

each instance of R^{bb} is, independently, selected from hydrogen, —OH, —OR^{aa}, —N(R^{cc})₂, —CN, —C(═O)R^{aa}, —C(═O)N(R^{cc})₂, —CO₂R^{aa}, —SO₂R^{aa}, —C(═NR^{cc})OR^{aa}, —C(═NR^{cc})N(R^{cc})₂, —SO₂N(R^{cc})₂, —SO₂R^{cc}, —SO₂OR^{cc}, —SOR^{aa}, —C(═S)N(R^{cc})₂, —C(═O)SR^{cc}, —C(═S)SR^{cc}, —P(═O)(R^{aa})₂, —P(═O)(OR^{cc})₂, —P(═O)(N(R^{cc})₂)₂, C₁₋₁₀ alkyl, C₁₋₁₀ perhaloalkyl, C₂₋₁₀ alkenyl, C₂₋₁₀ alkynyl, heteroC_{1-10 alkyl, heteroC}₂₋₁₀alkenyl, heteroC₂₋₁₀ alkynyl, C₃₋₁₀ carbocyclyl, 3-14 membered heterocyclyl, C₆₋₁₄ aryl, and 5-14 membered heteroaryl, or two R^{bb} groups are joined to form a 3-14 membered heterocyclyl or 5-14 membered heteroaryl ring, wherein each alkyl, alkenyl, alkynyl, heteroalkyl, heteroalkenyl, heteroalkynyl, carbocyclyl, heterocyclyl, aryl, and heteroaryl is independently substituted with 0, 1, 2, 3, 4, or 5 R^{dd} groups; wherein X⁻ is a counterion;

each instance of R^{cc} is, independently, selected from hydrogen, C₁₋₁₀ alkyl, C₁₋₁₀ perhaloalkyl, C₂₋₁₀ alkenyl, C₂₋₁₀ alkynyl, heteroC₁₋₁₀ alkyl, heteroC₂₋₁₀ alkenyl, heteroC₂₋₁₀ alkynyl, C₃₋₁₀ carbocyclyl, 3-14 membered heterocyclyl, C₆₋₁₄ aryl, and 5-14 membered heteroaryl, or two R^{cc} groups are joined to form a 3-14 membered heterocyclyl or 5-14 membered heteroaryl ring, wherein each alkyl, alkenyl, alkynyl, heteroalkyl, heteroalkenyl, heteroalkynyl, carbocyclyl, heterocyclyl, aryl, and heteroaryl is independently substituted with 0, 1, 2, 3, 4, or 5 R^{dd} groups;

each instance of R^{dd} is, independently, selected from halogen, —CN, —NO₂, —N₃, —SO₂H, —SO₃H, —OH, —OR^{ee}, —ON(R^{ff})₂, —N(R^{ff})₂, —N(R^{ff})₃⁺X⁻, —N(OR^{ee})R^{ff}, —SH, —SR^{ee}, —SSW^{ee}, —C(═O)R^{ee}, —CO₂H, —CO₂R^{ee}, —OC(═O)R^{ee}, —OCO₂R^{ee}, —C(═O)N(R^{ff})₂, —OC(═O)N(R^{ff})₂, —NR^{ff}C(═O)R^{ee}, —NR^{ff}CO₂R^{ee}, —NR^{ff}C(═O)N(R^{ff})₂, —C(═NR^{ff})OR^{cc}, —OC(═NR^{ff})R^{ee}, —OC(═NR^{ff})OR^{ee}, —C(═NR^{ff})N(R^{ff})₂, —OC(═NR^{ff})N(R^{ff})₂, —NR^{ff}C(═NR^{ff})N(R^{ff})₂, —NR^{ff}O₂R^{ee}, —SO₂N(R^{ff})₂, —SO₂R^{ee}, —SO₂OR^{ee}, —OSO₂R^{ee}, —S(═O)R^{ee}, —Si(R^{ee})₃, —OSi(R^{ee})₃, —C(═S)N(R^{ff})₂, —C(═O)SR^{ee}, —C(═S)SR^{ee}, —SC(═S)SR^{ee}, —P(═O)(OR^{ee})₂, —P(═O)(R^{ee})₂, —OP(═O)(R^{ee})₂, —OP(═O)(OR^{ee})₂, C₁₋₆ alkyl, C₁₋₆ perhaloalkyl, C₂₋₆ alkenyl, C₂₋₆ alkynyl, heteroC₁₋₆ alkyl, heteroC₂₋₆alkenyl, heteroC₂₋₆ alkynyl, C₃₋₁₀ carbocyclyl, 3-10 membered heterocyclyl, C₆₋₁₀ aryl, 5-10 membered heteroaryl, wherein each alkyl, alkenyl, alkynyl, heteroalkyl, heteroalkenyl, heteroalkynyl, carbocyclyl, heterocyclyl, aryl, and heteroaryl is independently substituted with 0, 1, 2, 3, 4, or 5 R^{gg} groups, or two geminal R^{dd} substituents can be joined to form ═O or ═S; wherein X⁻ is a counterion;

each instance of R^{ee} is, independently, selected from C₁₋₆ alkyl, C₁₋₆ perhaloalkyl, C₂₋₆ alkenyl, C₂₋₆ alkynyl, heteroC₁₋₆ alkyl, heteroC₂₋₆alkenyl, heteroC₂₋₆ alkynyl, C₃₋₁₀ carbocyclyl, C₆₋₁₀ aryl, 3-10 membered heterocyclyl, and 3-10 membered heteroaryl, wherein each alkyl, alkenyl, alkynyl, heteroalkyl, heteroalkenyl, heteroalkynyl, carbocyclyl, heterocyclyl, aryl, and heteroaryl is independently substituted with 0, 1, 2, 3, 4, or 5 R^{gg} groups;

each instance of e is, independently, selected from hydrogen, C₁₋₆ alkyl, C₁₋₆ perhaloalkyl, C₂₋₆ alkenyl, C₂₋₆ alkynyl, heteroC₁₋₆ alkyl, heteroC₂₋₆alkenyl, heteroC₂₋₆alkynyl, C₃₋₁₀ carbocyclyl, 3-10 membered heterocyclyl, C₆₋₁₀ aryl and 5-10 membered heteroaryl, or two R^{ff} groups are joined to form a 3-10 membered heterocyclyl or 5-10 membered heteroaryl ring, wherein each alkyl, alkenyl, alkynyl, heteroalkyl, heteroalkenyl, heteroalkynyl, carbocyclyl, heterocyclyl, aryl, and heteroaryl is independently substituted with 0, 1, 2, 3, 4, or 5 R^{gg} groups; and

each instance of R^{gg} is, independently, halogen, —CN, —NO₂, —N₃, —SO₂H, —SO₃H, —OH, —OC₁₋₆ alkyl, —ON(C₁₋₆ alkyl)₂, —N(C₁₋₆ alkyl)₂, —N(C₁₋₆ alkyl)₃^{+X}⁻, —NH(C₁₋₆ alkyl)₂⁺X⁻, —NH₂(C₁₋₆ alkyl)+X⁻, —NH₃⁺X⁻, —N(OC₁₋₆ alkyl)(C₁₋₆ alkyl), —N(OH)(C₁₋₆ alkyl), —NH(OH), —SH, —SC₁₋₆ alkyl, —SS(C₁₋₆ alkyl), —C(═O)(C₁₋₆ alkyl), —CO₂H, —CO₂(C₁₋₆ alkyl), —OC(═O)(C₁₋₆alkyl), —OCO₂(C₁₋₆ alkyl), —C(═O)NH₂, —C(═O)N(C₁₋₆ alkyl)₂, —OC(═O)NH(C₁₋₆ alkyl), —NHC(═O)(C₁₋₆ alkyl), —N(C₁₋₆ alkyl)C(═O)(C₁₋₆ alkyl), —NHCO₂(C₁₋₆ alkyl), —NHC(═O)N(C₁₋₆ alkyl)₂, —NHC(═O)NH(C₁₋₆ alkyl), —NHC(═O)NH₂, —C(═NH)O(C₁₋₆ alkyl), —OC(═NH)(C₁₋₆ alkyl), —OC(═NH)OC₁₋₆ alkyl, —C(═NH)N(C₁₋₆ alkyl)₂, —C(═NH)NH(C₁₋₆ alkyl), —C(═NH)NH₂, —OC(═NH)N(C₁₋₆ alkyl)₂, —OC(═NH)NH(C₁₋₆ alkyl), —OC(═NH)NH₂, —NHC(═NH)N(C₁₋₆ alkyl)₂, —NHC(═NH)NH₂, —NHSO₂(C₁₋₆ alkyl), —SO₂N(C₁₋₆ alkyl)₂, —SO₂NH(C₁₋₆ alkyl), —SO₂NH₂, —SO₂(C₁₋₆ alkyl), —SO₂O(C₁₋₆ alkyl), —OSO₂(C₁₋₆ alkyl), —SO(C₁₋₆ alkyl), —Si(C₁₋₆ alkyl)₃, —OSi(C₁₋₆ alkyl)₃—C(═S)N(C₁₋₆ alkyl)₂, C(═S)NH(C₁₋₆ alkyl), C(═S)NH₂, —C(═O)S(C₁₋₆ alkyl), —C(═S)SC₁₋₆ alkyl, —SC(═S)SC₁₋₆ alkyl, —P(═O)(OC₁₋₆ alkyl)₂, —P(═O)(C₁₋₆ alkyl)₂, —OP(═O)(C₁₋₆alkyl)₂, —OP(═O)(OC₁₋₆ alkyl)₂, C₁₋₆ alkyl, C₁₋₆ perhaloalkyl, C₂₋₆ alkenyl, C₂₋₆ alkynyl, heteroC₁₋₆ alkyl, heteroC₂₋₆alkenyl, heteroC₂₋₆alkynyl, C₃₋₁₀ carbocyclyl, C₆₋₁₀ aryl, 3-10 membered heterocyclyl, 5-10 membered heteroaryl; or two geminal Rgg substituents can be joined to form ═O or ═S; wherein X⁻ is a counterion.

As used herein, the term “halo” or “halogen” refers to fluorine (fluoro, —F), chlorine (chloro, —Cl), bromine (bromo, —Br), or iodine (iodo, —I).

The term “acyl” refers to a group having the general formula C(═O)R^{X1}, C(═O)OR^{X1}, —C(═O)—O—C(═O)R^{X1}, C(═O)SR^{X1}, C(═O)N(R^{X1})₂, C(═S)R^{x1}, C(═S)N(R^{X1})₂, —C(═S)O(R^{X1}), —C(═S)S(R^{X1}), —C(═NR^{X1})R^{X1}, —C(═NR^{X1})OR^{X1}, C(═NR^{X1})SR^{X1}, and —C(═NR^{X1})N(R^{X1})₂, wherein R^{X1} is hydrogen; halogen; substituted or unsubstituted hydroxyl; substituted or unsubstituted thiol; substituted or unsubstituted amino; substituted or unsubstituted acyl, cyclic or acyclic, substituted or unsubstituted, branched or unbranched aliphatic; cyclic or acyclic, substituted or unsubstituted, branched or unbranched heteroaliphatic; cyclic or acyclic, substituted or unsubstituted, branched or unbranched alkyl; cyclic or acyclic, substituted or unsubstituted, branched or unbranched alkenyl; substituted or unsubstituted alkynyl; substituted or unsubstituted aryl, substituted or unsubstituted heteroaryl, aliphaticoxy, heteroaliphaticoxy, alkyloxy, heteroalkyloxy, aryloxy, heteroaryloxy, aliphaticthioxy, heteroaliphaticthioxy, alkylthioxy, heteroalkylthioxy, arylthioxy, heteroarylthioxy, mono- or di-aliphaticamino, mono- or di-heteroaliphaticamino, mono- or di-alkylamino, mono- or di-heteroalkylamino, mono- or di-arylamino, or mono- or di-heteroarylamino; or two R^{x1} groups taken together form a 5- to 6-membered heterocyclic ring. Exemplary acyl groups include aldehydes (—CHO), carboxylic acids (—CO₂H), ketones, acyl halides, esters, amides, imines, carbonates, carbamates, and ureas. Acyl substituents include, but are not limited to, any of the substituents described herein, that result in the formation of a stable moiety (e.g., aliphatic, alkyl, alkenyl, alkynyl, heteroaliphatic, heterocyclic, aryl, heteroaryl, acyl, oxo, imino, thiooxo, cyano, isocyano, amino, azido, nitro, hydroxyl, thiol, halo, aliphaticamino, heteroaliphaticamino, alkylamino, heteroalkylamino, arylamino, heteroarylamino, alkylaryl, arylalkyl, aliphaticoxy, heteroaliphaticoxy, alkyloxy, heteroalkyloxy, aryloxy, heteroaryloxy, aliphaticthioxy, heteroaliphaticthioxy, alkylthioxy, heteroalkylthioxy, arylthioxy, heteroarylthioxy, acyloxy, and the like, each of which may or may not be further substituted).

A “counterion” or “anionic counterion” is a negatively charged group associated with a positively charged group in order to maintain electronic neutrality. An anionic counterion may be monovalent (i.e., including one formal negative charge). An anionic counterion may also be multivalent (i.e., including more than one formal negative charge), such as divalent or trivalent. Exemplary counterions include halide ions (e.g., F⁻, Cl⁻, Br⁻, I⁻), NO₃⁻, ClO₄⁻, OH⁻, H₂PO₄⁻, HCO₃⁻, HSO₄⁻, sulfonate ions (e.g., methansulfonate, trifluoromethanesulfonate, p-toluenesulfonate, benzenesulfonate, 10camphor sulfonate, naphthalene-2sulfonate, naphthalene-1-sulfonic acid-5-sulfonate, ethan-1-sulfonic acid-2-sulfonate, and the like), carboxylate ions (e.g., acetate, propanoate, benzoate, glycerate, lactate, tartrate, glycolate, gluconate, and the like), BF₄⁻, PF₄⁻, PF₆⁻, AsF₆⁻, SbF₆⁻, B[3,5-(CF₃)₂C₆H₃]₄]⁻, B(C₆F₅)₄⁻, BPh4⁻, Al(OC(CF₃)₃)4⁻, and carborane anions (e.g., CB₁₁H₁₂⁻ or (HCB₁₁Me₅Br₆)⁻). Exemplary counterions which may be multivalent include CO₃²⁻, HPO₄²⁻, PO₄³⁻, B₄O₇²⁻, SO₄²⁻, S₂O₃²⁻, carboxylate anions (e.g., tartrate, citrate, fumarate, maleate, malate, malonate, gluconate, succinate, glutarate, adipate, pimelate, suberate, azelate, sebacate, salicylate, phthalates, aspartate, glutamate, and the like), and carboranes.

The term “leaving group” is given its ordinary meaning in the art of synthetic organic chemistry and refers to an atom or a group capable of being displaced by a nucleophile. See, for example, Smith, March's Advanced Organic Chemistry 6th ed. (501-502). Examples of suitable leaving groups include, but are not limited to, halogen (such as F, Cl, Br, or I (iodine)), alkoxycarbonyloxy, aryloxycarbonyloxy, alkanesulfonyloxy, arenesulfonyloxy, alkyl-carbonyloxy (e.g., acetoxy), arylcarbonyloxy, aryloxy, methoxy, N,O-dimethylhydroxylamino, pixyl, and haloformates. In some cases, the leaving group is a sulfonic acid ester, such as toluenesulfonate (tosylate, -OTs), methanesulfonate (mesylate, -OMs), p-bromobenzenesulfonyloxy (brosylate, -OBs), —OS(═O)₂(CF₂)₃CF₃ (nonaflate, —ONf), or trifluoromethanesulfonate (triflate, —OTf). In some cases, the leaving group is a brosylate, such as p-bromobenzenesulfonyloxy. In some cases, the leaving group is a nosylate, such as 2-nitrobenzenesulfonyloxy. The leaving group may also be a phosphineoxide (e.g., formed during a Mitsunobu reaction) or an internal leaving group such as an epoxide or cyclic sulfate. Other non-limiting examples of leaving groups are water, ammonia, alcohols, ether moieties, thioether moieties, zinc halides, magnesium moieties, diazonium salts, and copper moieties. Further exemplary leaving groups include, but are not limited to, halo (e.g., chloro, bromo, iodo) and activated substituted hydroxyl groups (e.g., —OC(═O)SR^{aa}, —OC(═O)R^{aa}, —OCO₂R^{aa}, —OC(═O)N(R^{bb})₂, —OC(═NR^{bb})R^{aa}, —OC(═NR^{bb})OR^{aa}, —OC(═NR^{bb})N(R^{bb})₂, —OS(═O)R^{aa}, —OSO₂R^{aa}, —OP(R^{cc})₂, —OP(R^{cc})₃, —OP(═O)₂R^{aa}, —OP(═O)(R^{aa})₂, —OP(═O)(OR^{cc})₂, —OP(═O)₂N(R^{bb})₂, and —OP(═O)(NR^{bb})₂, wherein R^{aa}, R^{bb}, and R^{cc} are as defined herein).

As used herein, the term “hydroxyl” or “hydroxy” refers to the group —OH. The term “substituted hydroxyl” or “substituted hydroxyl,” by extension, refers to a hydroxyl group wherein the oxygen atom directly attached to the parent molecule is substituted with a group other than hydrogen, and includes groups selected from —OR^{aa}, —ON(R^{bb})₂, —OC(═O)SR^{aa}, —OC(═O)R^{aa}, —OCO₂R^{aa}, —OC(═O)N(R^{bb})₂, —OC(═NR^{bb})R^{aa}, —OC(═NR^{bb})OR^{aa}, —OC(═NR^{bb})N(R^{bb})₂, —OS(═O)R^{aa}, —OSO₂R^{aa}, —OSi(R^{aa})₃, —OP(R^{cc})₂, —OP(R^{cc})₃⁺X⁻, —OP(OR^{cc})₂, —OP(OR^{cc})₃⁺X⁻, —OP(═O)(R^{aa})₂, —OP(═O)(OR^{cc})₂, and —OP(═O)(N(R^{bb})₂)₂, wherein X⁻, R^{aa}, R^{bb}, and R^{cc} are as defined herein.

As used herein, the term “thiol” or “thio” refers to the group —SH. The term “substituted thiol” or “substituted thio,” by extension, refers to a thiol group wherein the sulfur atom directly attached to the parent molecule is substituted with a group other than hydrogen, and includes groups selected from —SR^{aa}, —S═SR^{cc}, —SC(═S)SR^{aa}, —SC(═O)SR^{aa}, —SC(═O)OR^{aa}, and —SC(═O)R^{aa}, wherein R^{aa} and R^{cc} are as described herein.

As used herein, the term, “amino” refers to the group —NH₂. The term “substituted amino,” by extension, refers to a monosubstituted amino, a disubstituted amino, or a trisubstituted amino, as described herein. In certain embodiments, the “substituted amino” is a monosubstituted amino or a disubstituted amino group.

As used herein, “monosubstituted amino” refers to an amino group wherein the nitrogen atom directly attached to the parent molecule is substituted with one hydrogen and one group other than hydrogen, and includes groups selected from —NH(R^{bb}), —NHC(═O)R^{aa}, —NHCO₂R^{aa}, —NHC(═O)N(R^{bb})₂, —NHC(═NR^{bb})N(R^{bb})₂, —NHSO₂R^{aa}, —NHP(═O)(OR^{cc})₂, and —NHP(═O)(N(R^{bb})₂)₂, wherein R^{aa}, R^{bb}, and R^{cc} are as defined herein, and wherein R^{bb} of the group —NH(R^{bb}) is not hydrogen.

As used herein, the term “disubstituted amino” refers to an amino group wherein the nitrogen atom directly attached to the parent molecule is substituted with two groups other than hydrogen, and includes groups selected from —N(R^{bb})₂, —NR^{bb}C(═O)R^{aa}, —NR^{bb}CO₂R^{aa}, —NRbbC(═O)N(R^{bb})₂, —NR^{bb}C(═NR^{bb})N(R^{bb})₂, —NR^{bb}SO₂R^{aa}, —NR^{bb}P(═O)(OR^{cc})₂, and —NR^{bb}P(═O)(N(R^{bb})₂)₂, wherein R^{aa}, R^{bb}, and R^{cc} are as defined herein, with the proviso that the nitrogen atom directly attached to the parent molecule is not substituted with hydrogen.

As used herein, the term “trisubstituted amino” refers to an amino group wherein the nitrogen atom directly attached to the parent molecule is substituted with three groups, and includes groups selected from —N(R^{bb})₃ and —N(R^{bb})₃⁺X⁻, wherein R^{bb} and X⁻ are as defined herein.

As used herein, the term “oxo” refers to the group ═O, and the term “thiooxo” refers to the group ═S.

Nitrogen atoms can be substituted or unsubstituted as valency permits, and include primary, secondary, tertiary, and quaternary nitrogen atoms. Exemplary nitrogen atom substituents include, but are not limited to, hydrogen, —OH, —OR^{aa}, —N(R^{cc})₂, —CN, —C(═O)R^{aa}, —C(═O)N(R^{cc})₂, —CO₂R^{aa}, —SO₂R^{aa}, —C(═NR^{bb})R^{aa}, —C(═NR^{cc})OR^{aa}, —C(═NR^{cc})N(R^{cc})₂, —SO₂N(R^{cc})₂, —SO₂R^{cc}, —SO₂OR^{cc}, —SOR^{aa}, —C(═S)N(R^{cc})₂, —C(═O)SR^{cc}, —C(═S)SR^{cc}, —P(═O)(OR^{cc})₂, —P(═O)(R^{aa})₂, —P(═O)(N(R^{cc})₂)₂, C₁₋₁₀ alkyl, C₁₋₁₀ perhaloalkyl, C₂₋₁₀ alkenyl, C₂₋₁₀ alkynyl, heteroC₁₋₁₀ alkyl, heteroC₂₋₁₀alkenyl, heteroC₂₋₁₀alkynyl, C₃₋₁₀ carbocyclyl, 3-14 membered heterocyclyl, C₆₋₁₄ aryl, and 5-14 membered heteroaryl, or two R^{cc} groups attached to an N atom are joined to form a 3-14 membered heterocyclyl or 5-14 membered heteroaryl ring, wherein each alkyl, alkenyl, alkynyl, heteroalkyl, heteroalkenyl, heteroalkynyl, carbocyclyl, heterocyclyl, aryl, and heteroaryl is independently substituted with 0, 1, 2, 3, 4, or 5 R^{dd} groups, and wherein R^{aa}, R^{bb}, R^{cc}, and R^{dd} are as defined herein.

In certain embodiments, the substituent present on the nitrogen atom is a nitrogen protecting group (also referred to herein as an “amino protecting group”). Nitrogen protecting groups include, but are not limited to, —OH, —OR^{aa}, —N(R^{cc})₂, —C(═O)R^{aa}, —C(═O)N(R^{cc})₂, —CO₂R^{aa}, —SO₂R^{aa}, —C(=NR^{cc})R^{aa}, —C(═NR^{cc})OR^{aa}, —C(═NR^{cc})N(R^{cc})₂, —SO₂N(R^{cc})₂, —SO₂R^{cc}, —SO₂OR^{cc}, —SOR^{aa}, —C(═S)N(R^{cc})₂, —C(═O)SR^{cc}, —C(═S)SR^{cc}, C ₁₋₁₀ alkyl (e.g., aralkyl, heteroaralkyl), C₂₋₁₀ alkenyl, C₂₋₁₀ alkynyl, heteroC₁₋₁₀ alkyl, heteroC₂₋₁₀ alkenyl, heteroC₂₋₁₀ alkynyl, C₃₋₁₀ carbocyclyl, 3-14 membered heterocyclyl, C₆₋₁₄ aryl, and 5-14 membered heteroaryl groups, wherein each alkyl, alkenyl, alkynyl, heteroalkyl, heteroalkenyl, heteroalkynyl, carbocyclyl, heterocyclyl, aralkyl, aryl, and heteroaryl is independently substituted with 0, 1, 2, 3, 4, or 5 R^{dd} groups, and wherein R^{aa}, R^{bb}, R^{cc} and R^{dd} are as defined herein. Nitrogen protecting groups are well known in the art and include those described in detail in Protecting Groups in Organic Synthesis, T. W. Greene and P. G. M. Wuts, 3r^{d} edition, John Wiley & Sons, 1999, incorporated herein by reference.

In certain embodiments, the substituent present on an oxygen atom is an oxygen protecting group (also referred to herein as an “hydroxyl protecting group”). Oxygen protecting groups include, but are not limited to, —R^{aa}, —N(R^{bb})₂, —C(═O)SR^{aa}, —C(═O)R^{aa}, —CO₂R^{aa}, —C(═O)N(R^{bb})₂, —C(═NR^{bb})R^{aa}, —C(═NR^{bb})OR^{aa}, —C(═NR^{bb})N(R^{bb})₂, —S(═O)R^{aa}, —SO₂R^{aa}, —Si(R^{aa})₃, P(R^{cc})₂, —P(R^{cc})₃⁺X⁻, —P(OR^{cc})₂, —P(OR^{cc})₃⁺X⁻, P(═O)(R^{aa})₂, P(═O)(OR^{cc})₂, and —P(═O)(N(R^{bb})₂)₂, wherein X⁻, R^{aa}, R^{bb}, and R^{cc} are as defined herein. Oxygen protecting groups are well known in the art and include those described in detail in Protecting Groups in Organic Synthesis, T. W. Greene and P. G. M. Wuts, 3^{rd} edition, John Wiley & Sons, 1999, incorporated herein by reference.

In certain embodiments, the substituent present on a sulfur atom is a sulfur protecting group (also referred to as a “thiol protecting group”). Sulfur protecting groups include, but are not limited to, —R^{aa}, —N(R^{bb})₂, —C(═O)SR^{aa}, —C(═O)R^{aa}, —CO₂R^{aa}, —C(═O)N(R^{bb})₂, —C(═NR^{bb})R^{aa}, —C(═NR^{bb})OR^{aa}, —C(═NR^{bb})N(R^{bb})₂, —S(═O)R^{aa}, —SO₂R^{aa}, —Si(R^{aa})₃, —P(R^{cc})₂, —P(R^{cc})₃⁺X⁻, —P(OR^{cc})₂, —P(OR^{cc})₃⁺X⁻, —P(═O)(R^{aa})₂, —P(═O)(OR^{cc})₂, and —P(═O)(N(R^{bb})₂)₂, wherein R^{aa}, R^{bb}, and R^{cc} are as defined herein. Sulfur protecting groups are well known in the art and include those described in detail in Protecting Groups in Organic Synthesis, T. W. Greene and P. G. M. Wuts, 3^{rd} edition, John Wiley & Sons, 1999, incorporated herein by reference. In certain embodiments, a sulfur protecting group is acetamidomethyl, t-Bu, 3-nitro-2-pyridine sulfenyl, 2-pyridine-sulfenyl, or triphenylmethyl.

These and other exemplary substituents are described in more detail in the Detailed Description, Examples, Figures, and Claims. The invention is not intended to be limited in any manner by the above exemplary listing of substituents.

### Other Definitions

The term “bridging ligand” or a ligand that “bridges” refers to a ligand that has the ability to connect two or more atoms (e.g., metal ions). The ligand may be atomic or polyatomic. The ligand that has the ability to connect atoms by coordination (e.g., coordinate covalent bond), ionic bonding, hydrogen bonding, covalent bonding, metallic bonding, dipole-dipole interaction, or van der Waals forces (e.g., London dispersion force). In certain embodiments, the bridging ligand is associated with a quantum dot (e.g., bonded to its surface), but not associated with another quantum dot (e.g., not bonded to its surface). In certain embodiments, the bridging ligand is associated with two quantum dots (e.g., bonded to the surface of each). In certain embodiments, the bridging ligand cross-links two quantum dots.

The term “cross-link,” as used herein, refers to a bond that links one quantum dot to another. In certain embodiments, a bridging ligand cross-links two quantum dots. The ligand may connect quantum dots by coordination (e.g., coordinate covalent bond), ionic bonding, hydrogen bonding, covalent bonding, metallic bonding, dipole-dipole interaction, or van der Waals forces (e.g., London dispersion force).

The term “dopant” or “doping agent” refers to an impurity that is inserted into a substance (e.g., in low concentrations) to alter the electrical or optical properties of the substance. In the case of crystalline substances, the atoms of the dopant commonly incorporate into the crystal lattice of the base material without imparting any substantial changes in the original crystal structure thereof. For example, a dopant atom may be substituted into a given crystal structure or may be present at an interstitial space. The dopant element may not exhibit any substantial crystalline peak in an X-ray diffraction spectrum. The presence (and/or the content) of dopant element may be confirmed by an X ray photoelectron spectroscopy, an energy dispersive X ray spectroscopy, ICP-AES, or TOF-SIMS. In certain embodiments, the crystalline materials are crystals of a semiconductor, e.g., for use in solid-state electronics. The addition of a dopant to a semiconductor, known as doping, has the effect of shifting the Fermi levels within the material. This results in a material with predominantly negative (n-type) or positive (p-type) charge carriers depending on the dopant variety. Pure semiconductors that have been altered by the presence of dopants are known as extrinsic semiconductors. Dopants are introduced into semiconductors in a variety of techniques, including solid sources, gases, spin on liquid, and ion implanting.

The term “organic compound” refers to any chemical compound that contains carbon. In certain embodiments, the organic compound is a hydrocarbon, i.e., an organic compound having at least one C—H bond.

The term “quantum dot” or “QD” refers to a semiconductor nanocrystal material in which excitons are confined in all three spatial dimensions, as distinguished from quantum wires (quantum confinement in only two dimensions), quantum wells (quantum confinement in only one dimension), and bulk semiconductors (unconfined). Many optical, electrical and chemical properties of the quantum dot may be strongly dependent on its size, and hence such properties may be modified or tuned by controlling its size. A quantum dot may generally be characterized as a particle, the shape of which may be spheroidal, ellipsoidal, or other shape. The size of the quantum dot may refer to a dimension characteristic of its shape or an approximation of its shape, and thus may be a diameter, a major axis, a predominant length, etc. The size of a quantum dot is on the order of nanometers, i.e., generally ranging from 1-1000 nm, but more typically ranging from 1-100 nm, 1-20 nm or 1-10 nm. In a plurality or ensemble of quantum dots, the quantum dots may be characterized as having an average size. The size distribution of a plurality of quantum dots may or may not be monodisperse. The quantum dot may have a core-shell configuration, in which the core and the surrounding shell may have distinct compositions. The quantum dot may also include ligands attached to its outer surface, or may be functionalized with other chemical moieties for a specific purpose.

The term “salt” refers to those salts which are derived from suitable inorganic and organic acids and bases. Examples of salts are salts of an amino group formed with inorganic acids such as hydrochloric acid, hydrobromic acid, phosphoric acid, sulfuric acid and perchloric acid or with organic acids such as acetic acid, oxalic acid, maleic acid, tartaric acid, citric acid, succinic acid or malonic acid or by using other methods used in the art such as ion exchange. Other salts include adipate, alginate, ascorbate, aspartate, benzenesulfonate, benzoate, bisulfate, borate, butyrate, camphorate, camphorsulfonate, citrate, cyclopentanepropionate, digluconate, dodecylsulfate, ethanesulfonate, formate, fumarate, glucoheptonate, glycerophosphate, gluconate, hemisulfate, heptanoate, hexanoate, hydroiodide, 2hydroxyethanesulfonate, lactobionate, lactate, laurate, lauryl sulfate, malate, maleate, malonate, methanesulfonate, 2-naphthalenesulfonate, nicotinate, nitrate, oleate, oxalate, palmitate, pamoate, pectinate, persulfate, 3phenylpropionate, phosphate, picrate, pivalate, propionate, stearate, succinate, sulfate, tartrate, thiocyanate, ptoluenesulfonate, undecanoate, valerate salts, and the like. Salts derived from appropriate bases include alkali metal, alkaline earth metal, ammonium and N⁺(C₁₋₄alkyl)₄ salts. Representative alkali or alkaline earth metal salts include sodium, lithium, potassium, calcium, magnesium, and the like. Further salts include ammonium, quaternary ammonium, and amine cations formed using counterions, such as halide, hydroxide, carboxylate, sulfate, phosphate, nitrate, lower alkyl sulfonate, and aryl sulfonate.

The term “inorganic salt” refers to any salt having all non-carbon atoms.

### EXAMPLES

In order that the present disclosure may be more fully understood, the following examples are set forth. The synthetic and biological examples described in this application are offered to illustrate the compounds, pharmaceutical compositions, and methods provided herein and are not to be construed in any way as limiting their scope.

### Example 1

### Chemical Doping

By using absorption spectroscopy measurements, chemical doping of PbS QDs is shown. When measuring the absorption (in transmission) of pristine QD films (no doping), a quantum confinement peak of the QDs is observed. Once the QDs were successfully doped the quantum confinement peak was quenched.

### Fabrication of Thin Film Samples for Absorption Apectroscopy Measurements

Quartz substrates were used. For sample fabrication, 5× PbS QD monolayers were used via spin casting. PbS QDs (with native oleic acid ligand) were placed in chloroform solvent at 5 mg/ml and spun at 800 rpm for 60 seconds.

The native ligand was exchanged to 1,2-ethanedithiol (EDT) in acetonitrile. The solution of EDT was added to the QD film and left to soak for 3 minutes before spin drying at 4,000 rpm for 60 seconds. The native ligand was then washed off using MeOH (spin cast, 4,000 rpm, 60 seconds). The steps above were repeated five times to form 5 layers. After the fifth layer the sample was baked on a hot plate at 100° C. for 30 minutes.

Dopant was added in solution to the resulting pristine device by spin casting. Dopants tested were: DMBI (2 mM in MeOH), LiClO₄ (8 mM in MeOH), DMBI:LiClO₄ 50:50 (2 mM:8 mM in MeOH), TDAE (2 mM in MeOH), and TDAE:LiClO₄ (50:50; 2 mM:8 mM in MeOH). Dopants were added to the film and left to soak for 3 minutes. This was followed by a dry spin of 4,000 rpm for 60 seconds. The device was then bakeed on a hotplate at 100° C. for 30 minutes.

### Absorption Spectroscopy Measurements

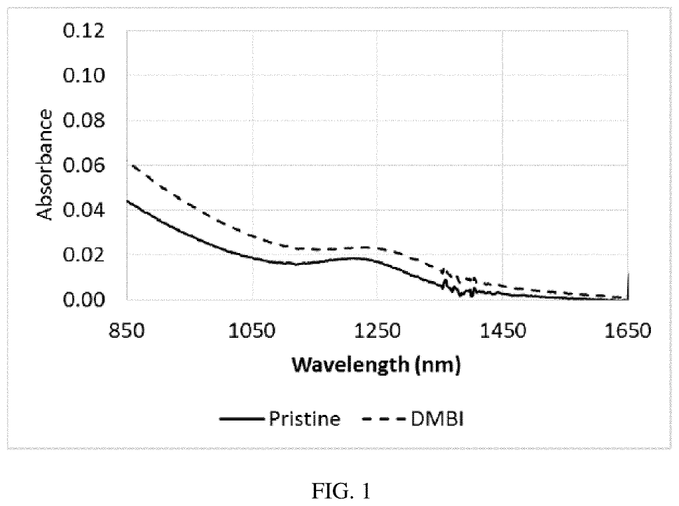

Absorption measurements were taken in transmission with a plain quartz substrate as a reference. The measurements were taken in air. Quantifying the doping level was completed by comparing the absorption of an undoped pristine sample to the absorption of the then doped same sample. In FIGS. 1-10 the quantum confinement peak of the quantum dots can be seen in the pristine samples. After successful doping a quenching of this peak was observed. The more the peak was quenched the more the QDs were doped.

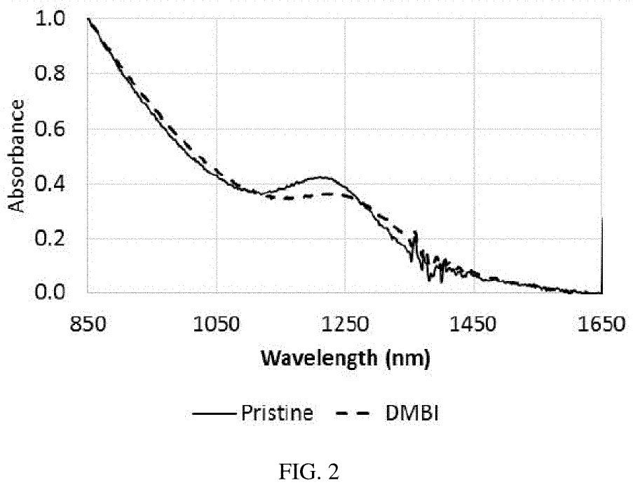

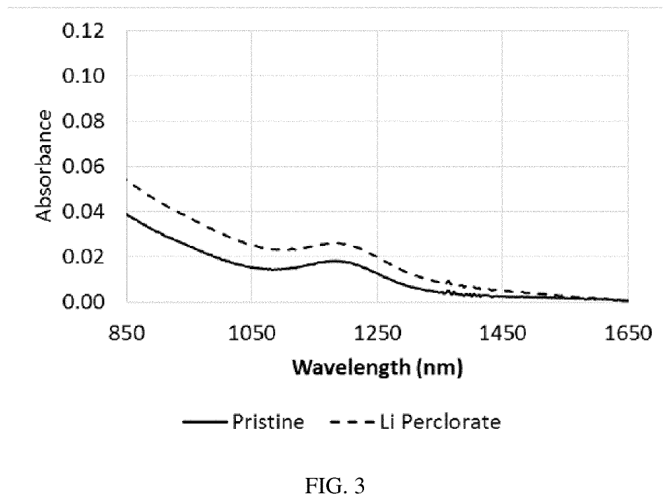

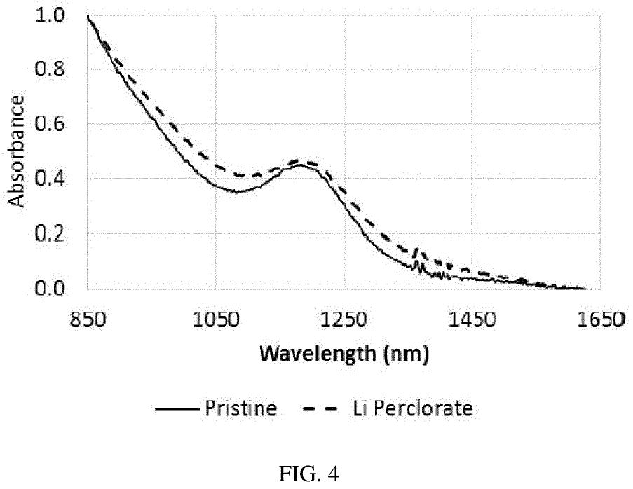

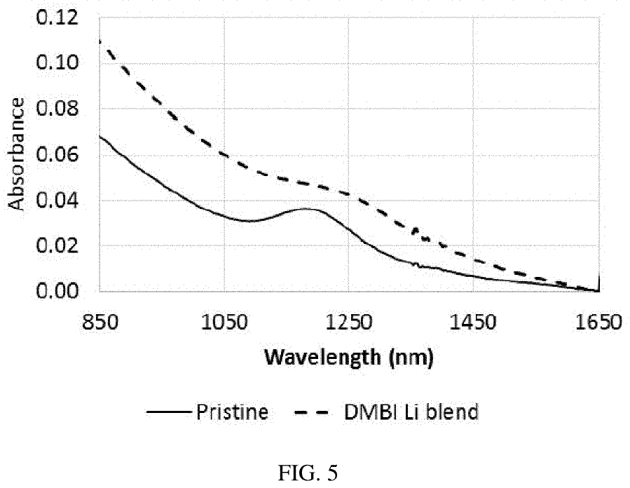

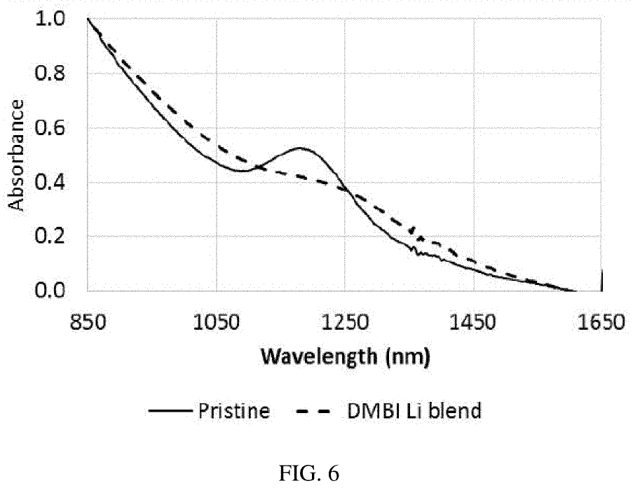

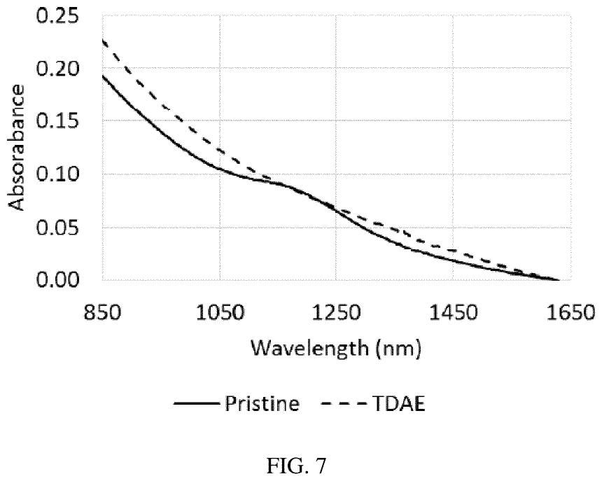

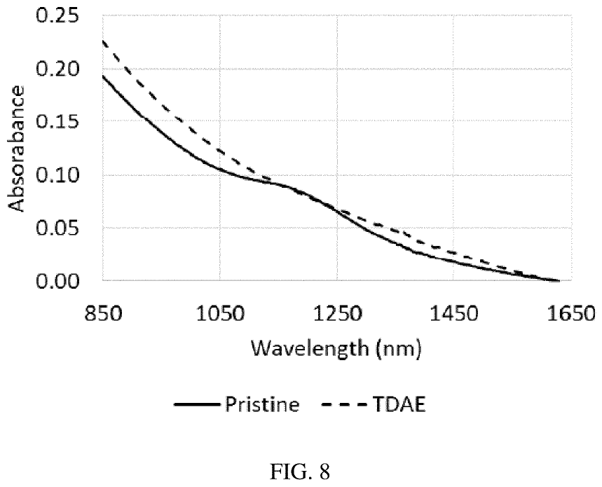

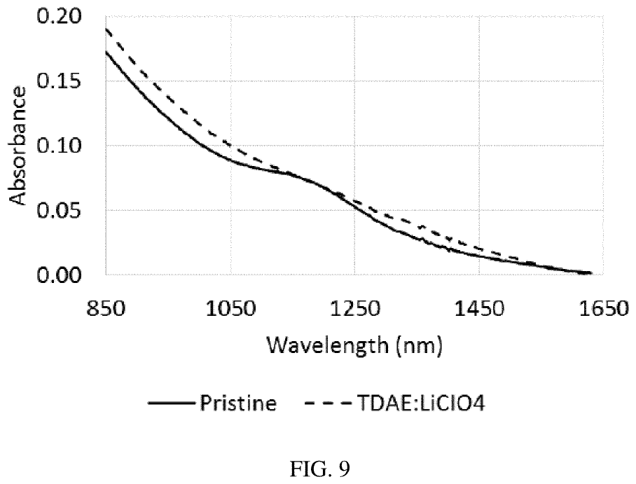

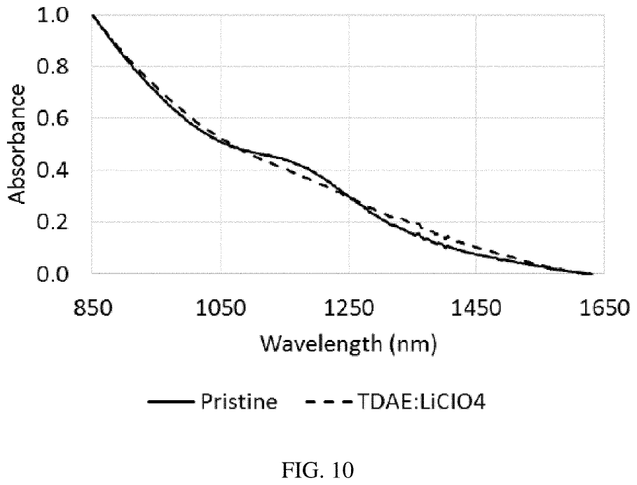

The quantum confinement peak around 1150 nm in the pristine spectra represents the first electronic band of the QDs. It is possible to fill the first band with 8 electrons. This would be indicated in the doped spectra by fully quenching the quantum confinement peak. For example, if the peak is quenched by 50%, then this would indicate a doping of 4 electrons per QD. By doping the QD lattice with DMBI only, a doping level of 2 electrons per QD was achieved (FIG. 1 and FIG. 2). When LiClO4 was included in a blend with DMBI, an increase in the doping to 4 electrons per dot is observed (FIG. 5 and FIG. 6). Including the lithium counter ions next to the QDs in the lattice may allow for charge neutrality, which is not possible by only using DMBI because it is too large to penetrate the lattice. Using only LiClO₄ to dope the films was not effective in doping the QDs (FIG. 3 and FIG. 4). An increase in doping was observed when using TDAE as the dopant (FIG. 7 and FIG. 8) as a doping level of 6 electrons in the first band was observed. The TDAE, which is smaller than DMBI, may be able to penetrate into the QD lattice more than DMBI via the film cracks in each layer of the QDs and, therefore, allow for greater doping. Combining TDAE and LiClO4 in a blend did not increase doping as much as the mixture of LiClO₄ and DMBI (FIG. 9 and FIG. 10).

### Example 2

### Field Effect Transistor (FET) Performance

Thin film QD layer FETs were fabricated and tested to demonstrate the impact of doping the QDs. The electrical performance was compared between pristine and doped devices.

### Fabrication of FETs

The substrate used was silicon wafer with SiO₂ grown on the top surface. The FETs were bottom gated. Gold electrodes were used for the FETs. The gate width was 20 μm. For sample fabrication, 5× PbS QD monolayers were used via spin casting. PbS QDs (with native oleic acid ligand) were placed in chloroform solvent at 5 mg/mL 4,000 rpm for 60 seconds. The ligand was exchanged to 1,2-ethanedithiol (EDT) in acetonitrile. The solution was added to the QD film and left to soak for 3 minutes before spin drying 4,000 rpm for 60 seconds. The native ligand was then washed off using MeOH with spin cast, 4,000 rpm for 60 seconds. The steps were repeated five times to form 5 layers. After the fifth layer the sample was baked on a hot plate at 100° C. for 30 minutes.

The dopant was then added in solution to the pristine device by spin casting. Dopants tested were as follows: DMBI (2 mM in MeOH), LiClO₄ (8 mM in MeOH), and DMBI:LiClO₄ (50:50; 2 mM:8 mM in MeOH).

### Results

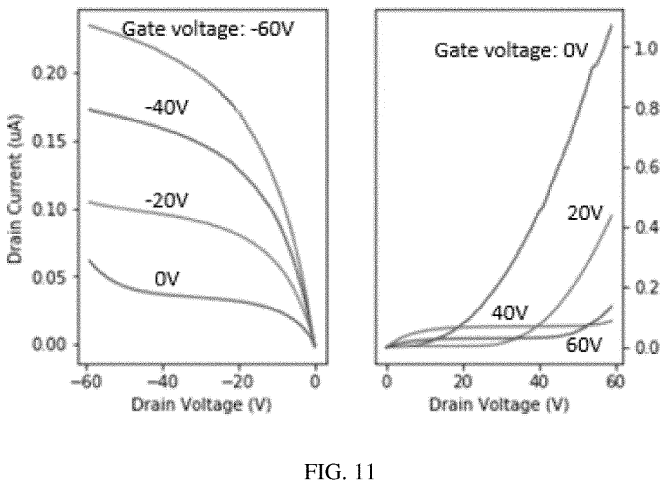

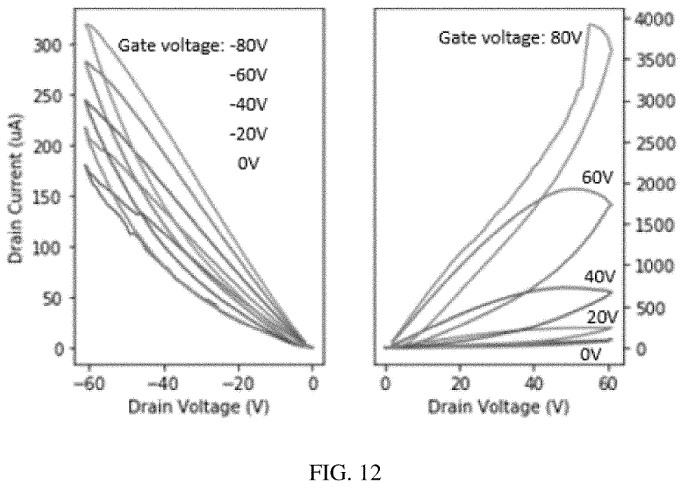

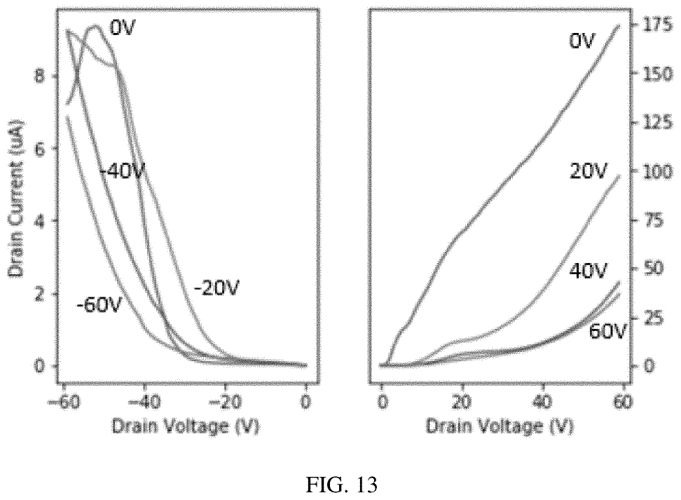

The pristine device exhibited p-type behavior (FIG. 11). An increase in drain current when doping the QD with DMBI:LiClO4 demonstrates improvement in performance, and n-type doping behavior was observed (FIG. 12). An increase in drain current was also observed when doping with DMBI only (FIG. 13), but not to the extent as the DMBI:LiClO4 blend. The DMBI-only doped device performed with p-type behavior.

### Example 3

### Ligand Design

The ligands tested were 1,2-ethanedithiol (EDT) (control), and ligands 1-3.

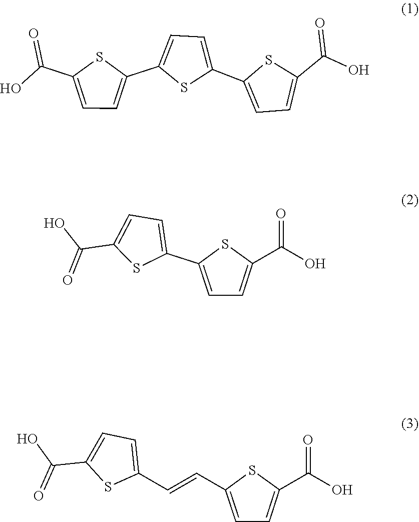 [SMILES: O=C(O)c1ccc(-c2ccc(-c3ccc(C(=O)O)s3)s2)s1 ; O=C(O)c1ccc(-c2ccc(C(=O)O)s2)s1 ; O=C(O)c1ccc(/C=C/c2ccc(C(=O)O)s2)s1]

### Test Format and Fabrication Procedure

Fabricated bottom gated field effect transistors (FETs) were prepared. Five monolayers of PbS QDs were spin cast onto silicon wafers with SiO2 insulating layer. Gold electrodes were used with gate width of 20 μm. PbS QDs were spun (60 seconds/4000 rpm) with native oleic acid ligand at 5 mg/mL in chloroform.

PbS QDs have an absorption peak at 1029 nm. For ligand exchange, the ligand was deposited onto the QD film and left to soak for 60 seconds in DMSO. This was followed by a drying step where the device was spun at 4000 rpm for 60 seconds. Next, the device was washed with DMSO to remove the detached native ligand: 60 seconds at 4000 rpm followed by a heating on hotplate at 100° C. for 60 seconds. The process was repeated five times to create five monolayers. The device was baked after the fifth layer on a hot plate for 30 minutes at 100° C.

### Results

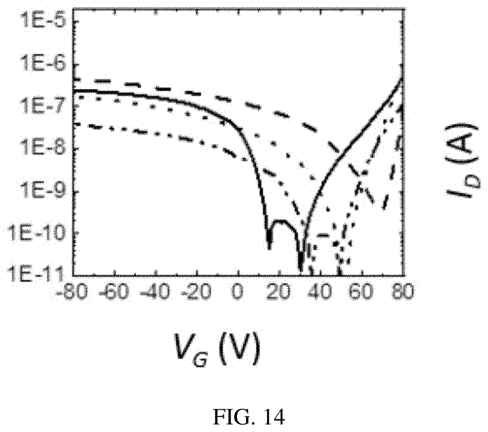

Ligands 1-3 are more p-type than EDT, which led to increased hole injection (for ligands 1-3) as compared to the EDT reference (FIG. 14). Increased hole conductivity with ligand 3 indicates that the vinylene unit between the thiophene units may improve hole conductivity as compared to ligands 1 and 2.

Ligand 1 had a greater hole conductivity compared to ligand 2 despite having greater length. Hence, the QDs are spaced farther apart without impacting electrical performance. This unexpected advantageous effect has the potential benefit to aid doping of the QDs by allowing more or larger chemical dopants to reside within the QD lattice.

### EQUIVALENTS AND SCOPE

In the claims articles such as “a,” “an,” and “the” may mean one or more than one unless indicated to the contrary or otherwise evident from the context. Claims or descriptions that include “or” between one or more members of a group are considered satisfied if one, more than one, or all of the group members are present in, employed in, or otherwise relevant to a given product or process unless indicated to the contrary or otherwise evident from the context. The disclosure includes embodiments in which exactly one member of the group is present in, employed in, or otherwise relevant to a given product or process. The disclosure includes embodiments in which more than one, or all of the group members are present in, employed in, or otherwise relevant to a given product or process.

Furthermore, the disclosure encompasses all variations, combinations, and permutations in which one or more limitations, elements, clauses, and descriptive terms from one or more of the listed claims is introduced into another claim. For example, any claim that is dependent on another claim can be modified to include one or more limitations found in any other claim that is dependent on the same base claim. Where elements are presented as lists, e.g., in Markush group format, each subgroup of the elements is also disclosed, and any element(s) can be removed from the group. It should it be understood that, in general, where the disclosure, or aspects described herein, is/are referred to as comprising particular elements and/or features, certain embodiments described herein or aspects described herein consist, or consist essentially of, such elements and/or features. For purposes of simplicity, those embodiments have not been specifically set forth in haec verba herein. It is also noted that the terms “comprising” and “containing” are intended to be open and permits the inclusion of additional elements or steps. Where ranges are given, endpoints are included. Furthermore, unless otherwise indicated or otherwise evident from the context and understanding of one of ordinary skill in the art, values that are expressed as ranges can assume any specific value or subrange within the stated ranges in different embodiments described herein, to the tenth of the unit of the lower limit of the range, unless the context clearly dictates otherwise.

This application refers to various issued patents, published patent applications, journal articles, and other publications, all of which are incorporated herein by reference. If there is a conflict between any of the incorporated references and the instant specification, the specification shall control. In addition, any particular embodiment of the present disclosure that falls within the prior art may be explicitly excluded from any one or more of the claims. Because such embodiments are deemed to be known to one of ordinary skill in the art, they may be excluded even if the exclusion is not set forth explicitly herein. Any particular embodiment described herein can be excluded from any claim, for any reason, whether or not related to the existence of prior art.

Those skilled in the art will recognize or be able to ascertain using no more than routine experimentation many equivalents to the specific embodiments described herein. The scope of the present embodiments described herein is not intended to be limited to the above Description, but rather is as set forth in the appended claims. Those of ordinary skill in the art will appreciate that various changes and modifications to this description may be made without departing from the spirit or scope of the present disclosure, as defined in the following claims.

What is claimed is:

1. A nanocrystal assembly comprising:
quantum dots;
a dopant comprising an organic compound; and
a ligand bridging the quantum dots.

2. The assembly of claim 1, wherein the quantum dots are colloidal quantum dots.

3. The assembly of claim 1, wherein the quantum dots comprise InSb, InGaP, PbS, PbSe, PbTe, PbI₂, HgS, HgTe, LaF₃, CdS, CulnS₂, CdTe, CuZnInS₂, CdSe, HfO₂, CIS, CZTS, YV(B)O₄, ZnS, ZrO₂, PbSₓSe₍₁₋ₓ₎, HgₓCd₍₁₋ₓ₎Te, InAs₍₁₋ₓ₎Sbₓ, or AlₓGa₍₁₋ₓ₎As, or combinations thereof.

4. The assembly of claim 1, wherein the quantum dots comprise PbS.

5. The assembly of claim 1, wherein the dopant is an n-type dopant.

6. The assembly of claim 1, wherein the dopant is of the formula: 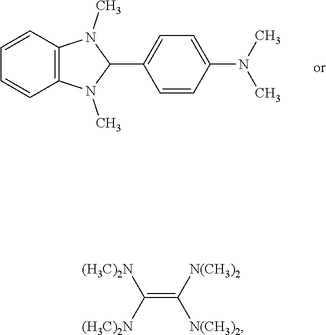
or salts thereof.

7. The assembly of claim 1, wherein the dopant further comprises an inorganic salt.

8. The assembly of claim 1, wherein the dopant further comprises LiClO₄.

9. The assembly of claim 1, wherein the ligand is of the formula: 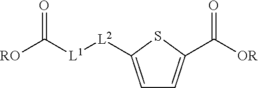
or a salt thereof, wherein:
each R is independently hydrogen, substituted or unsubstituted alkyl, substituted or unsubstituted aryl, substituted or unsubstituted heteroaryl, or substituted or unsubstituted heterocyclyl;
L¹ is a bond, substituted or unsubstituted heteroarylene, substituted or unsubstituted arylene, substituted or unsubstituted alkenylene, or substituted or unsubstituted alkynylene; and
L² is a bond, substituted or unsubstituted heteroarylene, substituted or unsubstituted arylene, substituted or unsubstituted alkenylene, or substituted or unsubstituted alkynylene; provided that L¹ and L² are not both a bond at the same time.

10. The assembly of claim 9, wherein:
each R is independently R is hydrogen or substituted or unsubstituted alkyl;
L¹ is a bond, substituted or unsubstituted heteroarylene, or substituted or unsubstituted alkenylene; and
L² is a bond, substituted or unsubstituted heteroarylene, or substituted or unsubstituted alkenylene.

11. The assembly of claim 9, wherein the ligand is of the formula: 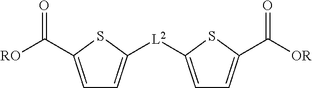
or a salt thereof.

12. The assembly of claim 9, wherein the ligand is of the formula: 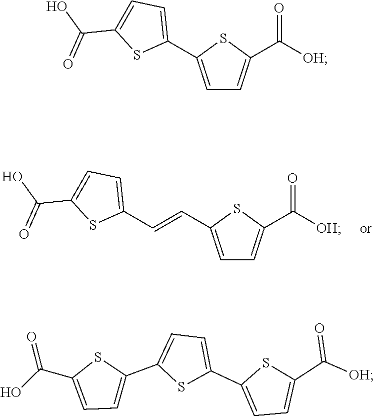
or a salt thereof.

13. The assembly of claim 1, wherein the quantum dots are cross-linked.

14. The assembly of claim 1, wherein substantially all of the quantum dots are cross-linked.

15. The assembly of claim 1, wherein the assembly comprises a thin film lattice.

16. A nanocrystal assembly comprising:
quantum dots;
a dopant; and
a ligand bridging the quantum dots, wherein the bridging ligand is of the formula: 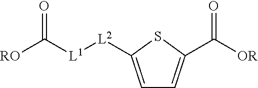
or a salt thereof,
wherein:
each R is independently R is hydrogen, substituted or unsubstituted alkyl, substituted or unsubstituted aryl, substituted or unsubstituted heteroaryl, or substituted or unsubstituted heterocyclyl;
L¹ is a bond, substituted or unsubstituted heteroarylene, substituted or unsubstituted arylene, substituted or unsubstituted alkenylene, or substituted or unsubstituted alkynylene; and
L² is a bond, substituted or unsubstituted heteroarylene, substituted or unsubstituted arylene, substituted or unsubstituted alkenylene, or substituted or unsubstituted alkynylene; provided that L¹ and L² are not both a bond at the same time.

17. A device comprising the assembly of claim 1.

18. The device of claim 17, wherein the device is a field effect transistor or a thermoelectric generator.

19. A method of preparing the device of claim 17, the method comprising solution processing the assembly.

20. A method of preparing the assembly of claim 1, the method comprising
(a) depositing the quantum dots on a substrate;
(b) combining the bridging ligand with the quantum dots such that any native ligand on the quantum dots is exchanged with the bridging ligand;
(c) spin casting to form a film;
(d) heating the film; and
(e) adding the dopant to the film in solvent via spin casting to form the assembly.
